(19) United States
(12) Patent Application Publication
(10) Pub. No.: US 2022/0293672 A1
(43) Pub. Date: Sep. 15, 2022

(54) DISPLAY DEVICE

(71) Applicant: SAMSUNG DISPLAY CO., LTD., Yongin-si (KR)

(72) Inventor: Jin Yun Kim, Asan-si (KR)

(21) Appl. No.: 17/559,914

(22) Filed: Dec. 22, 2021

(30) Foreign Application Priority Data
Mar. 9, 2021 (KR) 10-2021-0030766

(51) Int. Cl. H01L 27/15; H01L 25/075; H01L 33/38; H01L 33/62

(52) U.S. Cl. CPC H01L 27/156; H01L 25/0753; H01L 33/382; H01L 33/62

(57) ABSTRACT

A display device includes a first electrode and a second electrode extending in one direction on a substrate and spaced from each other, a first insulating layer on the first electrode and the second electrode, and a plurality of light emitting elements located on the first electrode and the second electrode, the plurality of light emitting elements being on the first insulating layer, wherein each of the first electrode and the second electrode includes a main electrode portion and a plurality of sub-electrode portions having a thickness smaller than that of the main electrode portion, the plurality of sub-electrode portions of each of the first electrode and the second electrode are connected to respective sides of the main electrode portion of the corresponding ones of the first electrode and the second electrode in the one direction.

### CROSS-REFERENCE TO RELATED APPLICATION

This application claims priority to and the benefit of Korean Patent Application No. 10-2021-0030766 filed on Mar. 9, 2021 in the Korean Intellectual Property Office, the entire content of which is incorporated by reference herein.

### BACKGROUND

### 1. Field

The present disclosure relates to a display device.

### 2. Description of the Related Art

The importance of display devices has steadily increased with the development of multimedia technology. In response thereto, various types of display devices such as an organic light emitting display (OLED), a liquid crystal display (LCD) and the like have been used.

As a device for displaying an image of a display device, there is a self-light emitting display device including a light emitting element. The self-light emitting display device includes an organic light emitting display device using an organic material as a light emitting material of a light emitting element, an inorganic light emitting display device using an inorganic material as a light emitting material of a light emitting element, or the like.

### SUMMARY

Aspects and features of embodiments of the present disclosure provide a display device having a structure in which electrodes have different heights depending on positions.

However, aspects and features of embodiments of the present disclosure are not limited to the ones set forth herein. The above and other aspects and features of embodiments of the present disclosure will become more apparent to one of ordinary skill in the art to which the present disclosure pertains by referencing the detailed description of the present disclosure given below.

In a display device according to one or more embodiments, electrodes include portions having different thicknesses, so that it is possible to reduce the number of light emitting elements that are lost during a manufacturing process while improving a degree of alignment of the light emitting elements.

However, aspects and features of embodiments of the present disclosure are not limited to the aforementioned aspects and features, and various other aspects and features of embodiments of the present disclosure are included in the specification.

According to one or more embodiments of the present disclosure, a display device includes a first electrode and a second electrode extending in one direction on a substrate and spaced from each other, a first insulating layer on the first electrode and the second electrode, and a plurality of light emitting elements located on the first electrode and the second electrode, the plurality of light emitting elements being on the first insulating layer, wherein each of the first electrode and the second electrode includes a main electrode portion and a plurality of sub-electrode portions having a thickness smaller than that of the main electrode portion, the plurality of sub-electrode portions of each of the first electrode and the second electrode are connected to respective sides of the main electrode portion of the corresponding ones of the first electrode and the second electrode in the one direction, and at least one of both ends of a light emitting element of the plurality of the light emitting elements is located on the main electrode portion of the first electrode or the second electrode.

Both sides of the main electrode portion of each of the first electrode and the second electrode, in the one direction, may be integrated and connected to the corresponding ones of the plurality of sub-electrode portions.

Each of the plurality of sub-electrode portions may have a thickness that decreases from one side that is in contact with the main electrode portion toward an other side.

The display device may further include a via layer between the substrate and the first and second electrodes, wherein each of the main electrode portions and the plurality of sub-electrode portions may be directly on the via layer.

In each of the first electrode and the second electrode, the plurality of sub-electrode portions may be spaced from each other in the one direction, and both sides of the main electrode portion of the first electrode or the second electrode in the one direction may be on the corresponding ones of the plurality of sub-electrode portions.

In one or more embodiments, each of the plurality of sub-electrode portions may include a first part, where the main electrode portion is located on the first part of the sub-electrode portion, and a second part connected to the first part and in contact with the main electrode portion, and the second part may have a thickness that decreases from one side that is in contact with the main electrode portion to an other side.

The display device may further include a via layer between the substrate and the first and second electrodes, wherein each of the plurality of sub-electrode portions may be located directly on the via layer, and the main electrode portion may have a bottom surface spaced from a top surface of the via layer.

The display device may further comprise a first bank pattern located between the substrate and the first electrode, and a second bank pattern located between the substrate and the second electrode, wherein the main electrode portion of the first electrode may be on the first bank pattern, and the main electrode portion of the second electrode may be on the second bank pattern.

Extension lengths of the first bank pattern and the second bank pattern in the one direction may be less than extension lengths of the main electrode portions of the first electrode and the second electrode in the one direction.

The display device may further include a bank layer around an emission area including the plurality of light emitting elements, and a sub-region on one side of the emission area in the one direction, wherein in each of the first electrode and the second electrode, the main electrode portion may be located in the emission area, and the plurality of sub-electrode portions may be located across the emission area and the sub-region over the bank layer.

The display device may further include a plurality of electrode contact holes through a via layer at a portion where the first electrode and the second electrode and the bank layer overlap, wherein in each of the first electrode and the second electrode, the plurality of sub-electrode portions may be on the electrode contact holes.

The display device may further include a first connection electrode on the first electrode and in contact with at least one of the plurality of light emitting elements, and a second connection electrode on the second electrode and in contact with at least one of the plurality of light emitting elements, wherein each of the first connection electrode and the second connection electrode may be located across the emission area and the sub-region.

The first connection electrode may be in contact with at least one of the plurality of the sub-electrode portions of the first electrode in the sub-region, and the second connection electrode may be in contact with at least one of the plurality of the sub-electrode portions of the second electrode in the sub-region.

According to one or more embodiments of the present disclosure, a display device includes a first electrode including a first main electrode portion extending in a first direction, and a plurality of first sub-electrode portions connected to both sides of the first main electrode portion in the first direction, a second electrode spaced from the first electrode in a second direction and extending in the first direction, a plurality of light emitting elements having one end located on the first electrode or the second electrode, a first connection electrode on the first electrode and in contact with some of the plurality of light emitting elements, and a second connection electrode on the second electrode and in contact with some other ones of the plurality of light emitting elements, wherein the first main electrode portion has a thickness greater than that of the first sub-electrode portions, and the plurality of light emitting element includes first light emitting elements having one end located on the first main electrode portion.

The second electrode may include a second main electrode portion extending in the first direction; and a plurality of second sub-electrode portions connected to both sides of the second main electrode portion in the first direction, and the first light emitting elements may have an other end located on the second main electrode portion.

The display device may further include a first insulating layer on the first electrode and the second electrode, wherein the first connection electrode may be on the first main electrode portion and at least one of the first sub-electrode portions may be in contact with at least one of the first sub-electrode portions through a first contact portion penetrating the first insulating layer, and the second connection electrode may be on the second main electrode portion and the plurality of second sub-electrode portions may be in contact with the plurality of second sub-electrode portions through a second contact portion penetrating the first insulating layer.

The display device may further include a bank layer that is around an emission area including the plurality of the light emitting elements, and a sub-region located on one side of the emission area in the first direction, wherein each of the first main electrode portion and the second main electrode portion may be located in the emission area, and each of the first sub-electrode portions and the second sub-electrode portions may be located across the emission area and the sub-region.

The display device may further include a third electrode located between the first electrode and the second electrode, and a fourth electrode spaced from the third electrode in the second direction with the second electrode interposed therebetween, wherein the first light emitting elements are on the first electrode and the third electrode, and the plurality of light emitting elements may further include second light emitting elements located on the second electrode and the fourth electrode.

Each of the second electrode, the third electrode, and the fourth electrode may include a main electrode portion extending in the first direction, and a plurality of sub-electrode portions connected to respective sides of the corresponding ones of the main electrode portions in the first direction, and the first light emitting element may have an other end on a third main electrode portion of the third electrode, and the second light emitting elements may have both ends located on a second main electrode portion of the second electrode and a fourth main electrode portion of the fourth electrode.

The fourth electrode may include a fourth main electrode portion extending in the first direction, and a plurality of fourth sub-electrode portions connected to both sides of the fourth main electrode portion in the first direction, each of the second electrode and the third electrode may have same thickness as the first main electrode portion, the first light emitting element may have an other end located on the third electrode, and the second light emitting elements may have both ends located on the second electrode and the fourth main electrode portion of the fourth electrode.

### BRIEF DESCRIPTION OF THE DRAWINGS

The above and other aspects and features of the present disclosure will become more apparent by describing in detail embodiments thereof with reference to the attached drawings, in which:

FIG. 1 is a schematic plan view of a display device according to one or more embodiments;

FIG. 2 is a plan view illustrating one pixel of a display device according to one or more embodiments;

FIG. 3 is a cross-sectional view taken along the line N1-N1′ of FIG. 2;

FIG. 4 is a cross-sectional view taken along the line N2-N2′ of FIG. 2;

FIG. 5 is a cross-sectional view taken along the line N3-N3′ of FIG. 2;

FIG. 6 is a schematic cutaway view of a light emitting element according to one or more embodiments;

FIGS. 7-9 illustrate cross sections of one electrode of a display device according to one or more embodiments;

FIG. 10 is a plan view illustrating a pixel of a display device according to one or more embodiments;

FIG. 11 is a cross-sectional view taken along the line N4-N4′ of FIG. 10;

FIG. 12 is a cross-sectional view taken along the line N5-N5′ of FIG. 10;

FIG. 13 is a plan view illustrating a sub-pixel of a display device according to one or more embodiments;

FIG. 14 is a cross-sectional view taken along the line N6-N6′ of FIG. 13;

FIG. 15 is a cross-sectional view taken along the line N7-N7′ of FIG. 13;

FIG. 16 is a plan view illustrating a sub-pixel of a display device according to one or more embodiments;

FIG. 17 is a cross-sectional view taken along the line N8-N8′ of FIG. 16; and

FIG. 18 is a diagram showing a cross section of one electrode of a display device according to one or more embodiments.

### DETAILED DESCRIPTION

Embodiments of the present disclosure will now be described more fully hereinafter with reference to the accompanying drawings, in which embodiments of the present disclosure are shown. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the scope of the present disclosure. Similarly, the second element could also be termed the first element.

Hereinafter, embodiments will be described with reference to the accompanying drawings.

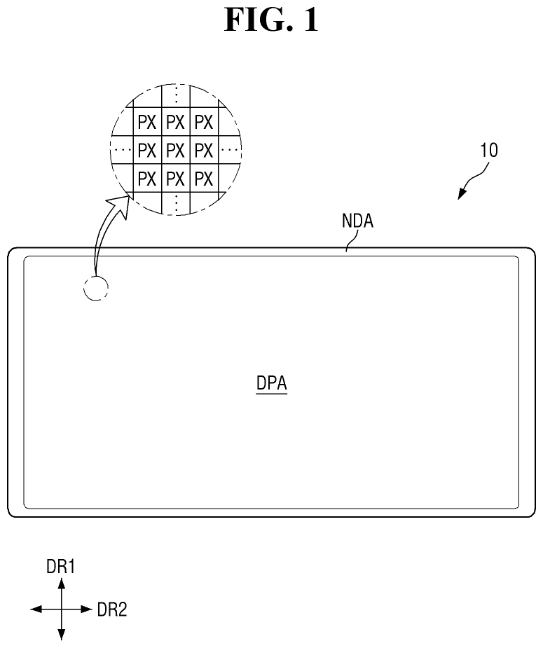

FIG. 1 is a schematic plan view of a display device according to one embodiment.

Referring to FIG. 1, a display device 10 displays a moving image or a still image. The display device 10 may refer to any electronic device providing a display screen. Examples of the display device 10 may include a television, a laptop computer, a monitor, a billboard, an Internet-of-Things (IoT) device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

The display device 10 includes a display panel that provides a display screen. Examples of the display panel may include an inorganic light emitting diode display panel, an organic light emitting display panel, a quantum dot light emitting display panel, a plasma display panel and a field emission display panel. In the following description, a case where an inorganic light emitting diode display panel is applied as a display panel will be exemplified, but the present disclosure is not limited thereto, and other display panels may be applied within the same scope of the technical spirit.

The shape of the display device 10 may be variously modified. For example, the display device 10 may have a shape such as a rectangular shape elongated in a horizontal direction, a rectangular shape elongated in a vertical direction, a square shape, a quadrilateral shape with rounded corners (vertices), another polygonal shape and a circular shape. The shape of a display area DPA of the display device 10 may also be similar to the overall shape of the display device 10. FIG. 1 illustrates a display device 10 having a rectangular shape elongated in a second direction DR2.

The display device 10 may include the display area DPA and a non-display area NDA around the edge or periphery of the display area DPA. The display area DPA is an area where an image can be displayed, and the non-display area NDA is an area where an image is not displayed. The display area DPA may also be referred to as an active region, and the non-display area NDA may also be referred to as a non-active region. The display area DPA may substantially occupy the center (or the central region) of the display device 10.

The display area DPA may include a plurality of pixels PX. The plurality of pixels PX may be arranged in a matrix. The shape of each pixel PX may be a rectangular or square shape in a plan view. However, the present disclosure is not limited thereto, and it may be a rhombic shape in which each side is inclined with respect to one direction. The pixels PX may be disposed in a stripe arrangement structure or a PENTILE® arrangement structure, but the present disclosure is not limited thereto. This PENTILE® arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. In addition, each of the pixels PX may include one or more light emitting elements that emit light of a specific wavelength band to display a specific color.

The non-display area NDA may be disposed around the display area DPA. The non-display area NDA may completely or partially be around (or surround) the display area DPA. The display area DPA may have a rectangular shape, and the non-display area NDA may be disposed adjacent to four sides of the display area DPA. The non-display area NDA may form a bezel of the display device 10. Wires or circuit drivers included in the display device 10 may be disposed in the non-display area NDA, or external devices may be mounted thereon.

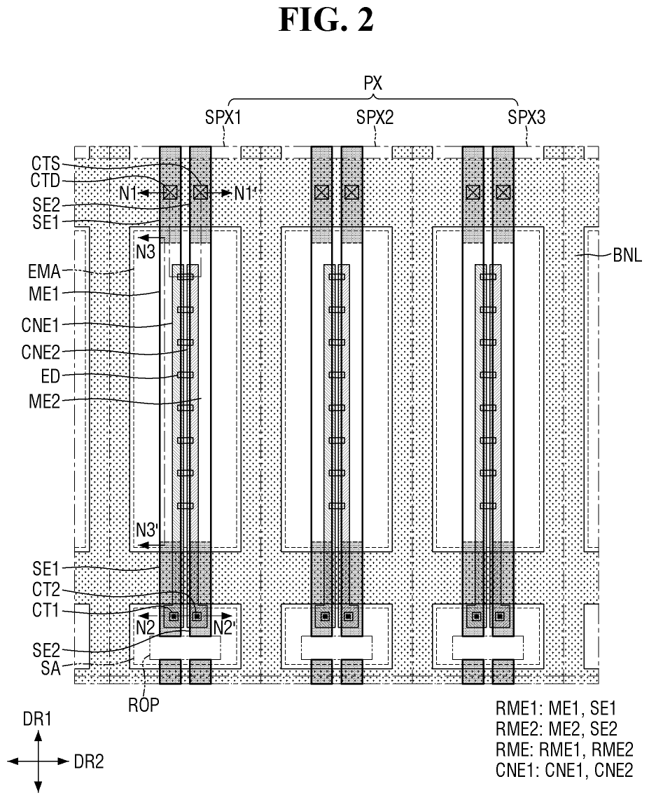

FIG. 2 is a plan view illustrating one pixel of a display device according to one or more embodiments.

Referring to FIG. 2, each of the pixels PX of the display device 10 may include a plurality of sub-pixels SPXn (n ranging from 1 to 3). For example, one pixel PX may include a first sub-pixel SPX1, a second sub-pixel SPX2, and a third sub-pixel SPX3. The first sub-pixel SPX1 may emit light of a first color, the second sub-pixel SPX2 may emit light of a second color, and the third sub-pixel SPX3 may emit light of a third color. For example, the first color may be blue, the second color may be green, and the third color may be red. However, the present disclosure is not limited thereto, and all the sub-pixels SPXn may emit light of the same color. In one embodiment, each of the sub-pixels SPXn may emit blue light. In addition, although it is illustrated in the drawing that one pixel PX includes three sub-pixels SPXn, the present disclosure is not limited thereto, and the pixel PX may include a larger number of sub-pixels SPXn.

Each sub-pixel SPXn of the display device 10 may include an emission area EMA and a non-emission area. The emission area EMA may be an area in which the light emitting element ED is disposed to emit light of a specific wavelength band. The non-emission area may be a region in which the light emitting element ED is not disposed and a region from which light is not emitted because light emitted from the light emitting element ED does not reach this area.

The emission area may include an area in which the light emitting element ED is disposed, and an area adjacent to the light emitting element ED to emit light emitted from the light emitting element ED. Without being limited thereto, the emission area EMA may also include an area in which light emitted from the light emitting element ED is reflected or refracted by another member and emitted. The plurality of light emitting elements ED may be disposed in each sub-pixel SPXn, and the emission area EMA may be formed to include an area where the light emitting elements ED are disposed and an area adjacent thereto.

Although it is shown in the drawing that the sub-pixels SPXn have the emission areas EMA that are substantially identical in size, the present disclosure is not limited thereto. In one or more embodiments, the emission areas EMA of the sub-pixels SPXn may have different sizes according to a color or wavelength band of light emitted from the light emitting element ED disposed in each sub-pixel.

In addition, each sub-pixel SPXn may further include a sub-region SA disposed in the non-emission area. The sub-region SA may be disposed at one side of the emission area EMA in the first direction DR1, and may be disposed between the emission areas EMA of the sub-pixels SPXn adjacent in the first direction DR1. For example, the emission areas EMA and the sub-regions SA may be repeatedly arranged along the second direction DR2, while being alternately arranged along the first direction DR1. However, the present disclosure is not limited thereto, and the arrangement of the emission areas EMA and the sub-regions SA in the plurality of pixels PX may be different from that shown in FIG. 2.

A bank layer BNL may be disposed between the sub-regions SA and between the emission areas EMA, and the distance therebetween may vary with the width of the bank layer BNL. Light may not be emitted from the sub-region SA because the light emitting element ED is not disposed in the sub-region SA, but an electrode RME disposed in each sub-pixel SPXn may be partially disposed in the sub-region SA. The electrodes RME disposed in different sub-pixels SPXn may be disposed to be separated by a separation portion ROP of the sub-region SA.

The bank layer BNL may include portions extending in the first direction DR1 and the second direction DR2 in a plan view to be arranged in a grid pattern over the entire surface of the display area DPA. The bank layer BNL may be disposed along the boundaries between the sub-pixels SPXn to delimit the neighboring sub-pixels SPXn. Further, the bank layer BNL may be disposed so as to be around (or surround) the emission area EMA of each sub-pixel SPXn to distinguish the emission areas EMA.

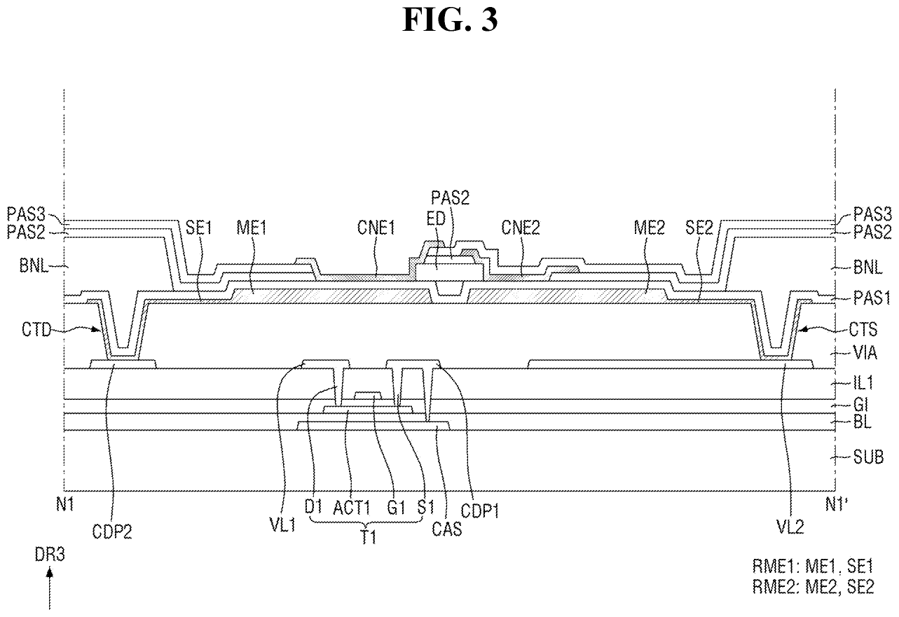

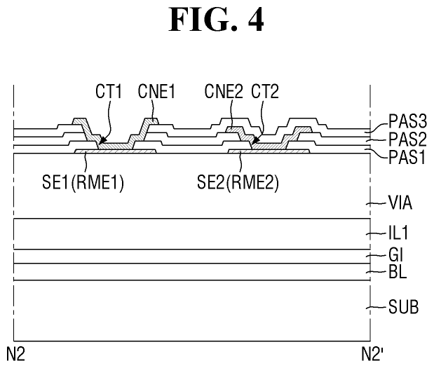

FIG. 3 is a cross-sectional view taken along the line N1-N1′ of FIG. 2. FIG. 4 is a cross-sectional view taken along the line N2-N2′ of FIG. 2. FIG. 3 shows a cross section across both ends of the light emitting element ED disposed in the first sub-pixel SPX1 in one pixel PX of FIG. 2, and FIG. 4 shows a cross section across contact portions CT1 and CT2 arranged in the sub-region SA of the first sub-pixel SPX1.

Referring to FIGS. 3 and 4 in conjunction with FIG. 2, the display device 10 may include a first substrate SUB and a semiconductor layer, a plurality of conductive layers, and a plurality of insulating layers disposed on the first substrate SUB. The semiconductor layer, the conductive layers, and the insulating layers may each constitute a circuit layer and a display element layer of the display device 10.

For example, the first substrate SUB may be an insulating substrate. The first substrate SUB may be made of an insulating material such as glass, quartz, or polymer resin. Further, the first substrate SUB may be a rigid substrate, but may also be a flexible substrate that can be bent, folded or rolled.

A first conductive layer may be on the first substrate SUB. The first conductive layer includes a lower metal layer CAS that is disposed to overlap an active layer ACT1 of a first transistor T1 in a thickness direction of the substrate SUB (e.g., a third direction DR3). The lower metal layer CAS may include a material of blocking light to prevent light from reaching the active layer ACT1 of the first transistor T1. However, the lower metal layer CAS may be omitted.

The buffer layer BL may be disposed on the lower metal layer CAS and the first substrate SUB. The buffer layer BL may be formed on the first substrate SUB to protect the transistors of the pixel PX from moisture permeating through the first substrate SUB susceptible to moisture permeation, and may perform a surface planarization function.

The semiconductor layer is disposed on the buffer layer BL. The semiconductor layer may include the active layer ACT1 of the first transistor T1. The active layer ACT1 may be arranged to partially overlap the gate electrode G1 of the second conductive layer, to be described later, in the thickness direction of the substrate SUB (e.g., the third direction DR3).

The semiconductor layer may include polycrystalline silicon, monocrystalline silicon, oxide semiconductor, and the like. In another embodiment, the semiconductor layer may include polycrystalline silicon. The oxide semiconductor may be an oxide semiconductor containing indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), or indium gallium zinc tin oxide (IGZTO).

Although it is illustrated in the drawing that one first transistor T1 is disposed in the sub-pixel SPXn of the display device 10, but the present disclosure is not limited thereto, and the display device 10 may include a larger number of transistors.

The first gate insulating layer GI is disposed on the semiconductor layer and the buffer layer BL. The first gate insulating layer GI may serve as a gate insulating layer of the first transistor T1.

The second conductive layer is disposed on the first gate insulating layer GI. The second conductive layer may include the gate electrode G1 of the first transistor T1. The gate electrode G1 may be arranged to overlap the channel region of the active layer ACT1 in the third direction DR3, which is the thickness direction of the substrate SUB.

A first interlayer insulating layer IL1 is disposed on the second conductive layer. The first interlayer insulating layer IL1 may function as an insulating layer between the second conductive layer and other layers disposed thereon, and may protect the second conductive layer.

A third conductive layer is disposed on the first interlayer insulating layer IL1. The third conductive layer may include a first voltage wire VL1, a second voltage wire VL2, and a plurality of conductive patterns CDP1 and CDP2 that are arranged in the display area DPA.

The first voltage wire VL1 may be applied with a high potential voltage (or a first power voltage) transmitted to the first electrode RME1, and the second voltage wire VL2 may be applied with a low potential voltage (or a second power voltage) transmitted to the second electrode RME2. A part of the first voltage wire VL1 may be in contact with the active layer ACT1 of the first transistor T1 through the contact hole penetrating the first interlayer insulating layer IL1 and the first gate insulating layer GI. The first voltage wire VL1 may serve as a first drain electrode D1 of the first transistor T1. The second voltage wire VL2 may be directly connected to the second electrode RME2 to be described later.

A first conductive pattern CDP1 may be in contact with the active layer ACT1 of the first transistor T1 through the contact hole penetrating the first interlayer insulating layer IL1 and the first gate insulating layer GI. Further, the first conductive pattern CDP1 may be in contact with the lower metal layer CAS through another contact hole penetrating the first interlayer insulating layer IL1, the first gate insulating layer GI, and the buffer layer BL. The first conductive pattern CDP1 may serve as a first source electrode S1 of the first transistor T1.

The second conductive pattern CDP2 may be connected to the first electrode RME1 to be described later. Further, the second conductive pattern CDP2 may be electrically connected to the first transistor T1 through the first conductive pattern CDP1. Although it is illustrated in the drawing that the first conductive pattern CDP1 and the second conductive pattern CDP2 are separated from each other, the second conductive pattern CDP2 and the first conductive pattern CDP1 may be integrated to form one pattern in one or more embodiments. The first transistor T1 may transmit the first power voltage applied from the first voltage wire VL1 to the first electrode RME1.

On the other hand, although it is illustrated in the drawing that the first conductive pattern CDP1 and the second conductive pattern CDP2 are formed at the same layer, the present disclosure is not limited thereto. In some one or more embodiments, the second conductive pattern CDP2 may be formed as a fourth conductive layer disposed on the third conductive layer with one or more insulating layers interposed between the first conductive pattern CDP1 and another conductive layer, e.g., the third conductive layer. In such a case, the first and second voltage wires VL1 and VL2 may also be formed as the fourth conductive layer instead of the third conductive layer, and the first voltage wire VL1 may be electrically connected to the drain electrode D1 of the first transistor T1 through another conductive pattern.

The buffer layer BL, the first gate insulating layer GI, and the first interlayer insulating layer IL1 described above may be formed of a plurality of inorganic layers stacked in an alternating manner. For example, the buffer layer BL, the first gate insulating layer GI, and the first interlayer insulating layer IL1 may be formed as a double layer formed by stacking, or a multilayer formed by alternately stacking, inorganic layers including at least one of silicon oxide (SiOx), silicon nitride (SiNx), or silicon oxynitride (SiOxNy). However, the present disclosure is not limited thereto, and the buffer layer BL, the first gate insulating layer GI, and the first interlayer insulating layer IL1 may be formed as a single inorganic layer containing the above-described insulating material. Further, in one or more embodiments, the first interlayer insulating layer IL1 may be made of an organic insulating material such as polyimide (PI) or the like.

The second conductive layer and the third conductive layer may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof. However, the present disclosure is not limited thereto.

A via layer VIA is disposed on the third conductive layer in the display area DPA. The via layer VIA may include an organic insulating material, for example, an organic insulating material such as polyimide (PI), to perform a surface planarization function.

The plurality of electrodes RME (RME1 and RME2), the bank layer BNL, the plurality of light emitting elements ED, and a plurality of connection electrodes CNE (CNE1 and CNE2) are arranged as the display element layer on the via layer VIA. Further, a plurality of insulating layers PAS1, PAS2, and PAS3 may be disposed on the via layer VIA.

The plurality of electrodes RME have a shape extending in one direction and are disposed for each sub-pixel SPXn. The plurality of electrodes RME may extend in the first direction DR1 to be disposed across the emission area EMA of the sub-pixel SPXn, and may be disposed to be spaced from each other in the second direction DR2. The electrodes RME may be electrically connected to the light emitting elements ED. The electrodes RME may be connected to the light emitting element ED through the connection electrodes CNE (CNE1 and CNE2) to be described later, and may transmit an electrical signal applied from the conductive layer disposed therebelow to the light emitting element ED.

The display device 10 includes the first electrode RME1 and the second electrode RME2 arranged in each sub-pixel SPXn. The first electrode RME1 is located on the left side with respect to the center of the emission area EMA, and the second electrode RME2 is located on the right side with respect to the center of the emission area EMA while being spaced from the first electrode RME1 in the second direction DR2. The first electrode RME1 and the second electrode RME2 may be partially arranged in the corresponding sub-pixel SPXn and the sub-region SA over the bank layer BNL. The first electrode RME1 and the second electrode RME2 of different sub-pixels SPXn (that are adjacent in the first direction DR1) may be separated with respect to the separation portion ROP located in the sub-region SA of one sub-pixel SPXn.

The first electrode RME1 and the second electrode RME2 may be connected to the third conductive layer through a first electrode contact hole CTD and a second electrode contact hole CTS, respectively that are formed in portions overlapping the bank layer BNL in the third direction DR3. The first electrode RME1 may be in contact with the second electrode pattern CDP2 through the first electrode contact hole CTD penetrating the via layer VIA thereunder. The second electrode RME2 may be in contact with the second voltage wire VL2 through the second electrode contact hole CTS penetrating the via layer VIA thereunder. The first electrode RME1 may be electrically connected to the first transistor T1 through the second electrode pattern CDP2 and the first electrode pattern CDP1 and may receive the first power voltage. The second electrode RME2 may be electrically connected to the second voltage wire VL2 and may receive the second power voltage.

On the other hand, the display device 10 may include portions where the electrodes RME have different heights and thicknesses depending on positions. In one or more embodiments, the electrodes RME may include main electrode portions ME1 and ME2 and sub-electrode portions SE1 and SE2 having thicknesses and heights that are less than those of the main electrode portions ME1 and ME2, respectively. In the display device 10, because the electrodes RME have different thicknesses depending on positions, it is possible to improve a degree of alignment of the light emitting elements ED arranged on the electrodes RME to be described later. For example, the light emitting elements ED may be concentrated on specific portions of the electrodes RME, so that it is possible to reduce the number of light emitting elements ED that are lost during the manufacturing process. A detailed description thereof will be given later with reference to other drawings.

In one or more embodiments, the first insulating layer PAS1 may be disposed on the via layer VIA and the plurality of electrodes RME. The first insulating layer PAS1 may protect the plurality of electrodes RME and insulate electrodes RME different from each other. For example, the first insulating layer PAS1 is disposed to cover the electrodes RME before the bank layer BNL is formed, so that it is possible to prevent the electrodes RME from being damaged in a process of forming the bank layer BNL. In addition, the first insulating layer PAS1 may prevent the light emitting element ED disposed thereon from being damaged by direct contact with other members.

In one or more embodiments, the first insulating layer PAS1 may have stepped portions such that the top surface thereof is partially depressed between the electrodes RME that are spaced in the second direction DR2. The light emitting element ED may be disposed on the top surface of the first insulating layer PAS1, where the stepped portions are formed, and thus a space may remain between the light emitting element ED and the first insulating layer PAS1.

In one or more embodiments, the first insulating layer PAS1 may include a plurality of openings exposing a part of the top surfaces of the electrodes RME. For example, the first insulating layer PAS1 may include the contact portions CT1 and CT2 exposing a part of the top surfaces of the electrodes RME in the sub-region SA. The first contact portion CT1 may be disposed on the first electrode RME1 in the sub-region SA to expose the top surface of the first electrode RME1, and the second contact portion CT2 may be disposed on the second electrode RME2 in the sub-region SA to expose the top surface of the second electrode RME2. The connection electrodes CNE to be described later may be in contact with the electrodes RME exposed through the first contact portion CT1 and the second contact portion CT2. Further, the first insulating layer PAS1 may open the top surface of the via layer VIA at the separation portion ROP where the electrodes RME of different sub-pixels SPXn are separated.

The bank layer BNL may be disposed on the first insulating layer PAS1. The bank layer BNL may include portions extending in the first direction DR1 and the second direction DR2, and may be around (or surround) the sub-pixels SPXn. Further, the bank layer BNL may be around (or surround) and distinguish the emission area EMA and the sub-region SA of each sub-pixel SPXn, and may be around (or surround) the outermost part of the display area DPA and distinguish the display area DPA and the non-display area NDA. The bank layer BNL is disposed in the entire display area DPA to form a grid pattern, and the regions opened by the bank layer BNL in the display area DPA may be the emission area EMA and the sub-region SA.

The bank layer BNL may have a constant height. The bank layer BNL may prevent ink from overflowing to adjacent sub-pixels SPXn in an inkjet printing process during the manufacturing process of the display device 10. The bank layer BNL may contain an organic insulating material such as polyimide.

The plurality of light emitting elements ED may be arranged on the first insulating layer PAS1. The light emitting element ED may have a shape extending in one direction, and may be disposed such that one direction in which the light emitting element ED extends is parallel to the first substrate SUB. As will be described later, the light emitting element ED may include a plurality of semiconductor layers arranged along one direction in which the light emitting element ED extends, and the plurality of semiconductor layers may be sequentially arranged along the direction parallel to the top surface of the first substrate SUB. However, the present disclosure is not limited thereto, and the plurality of semiconductor layers may be arranged in the direction perpendicular to the first substrate SUB when the light emitting element ED has another structure.

The plurality of light emitting elements ED may be arranged on the electrodes RME spaced from each other in the second direction DR2. The extension length of the light emitting element ED may be greater than the gap between the electrodes RME spaced apart from each other in the second direction DR2. The light emitting elements ED may have at least one end disposed on any one of the electrodes RME that are different from each other, or may have both ends disposed on the electrodes RME that are different from each other, respectively. A direction in which each electrode RME is extended and a direction in which the light emitting element ED is extended may be substantially perpendicular to each other. The light emitting elements ED may be disposed to be spaced from each other along the first direction DR1 in which the electrodes RME extend, and may be aligned substantially parallel to each other. However, the present disclosure is not limited thereto, and the light emitting elements ED may each be arranged to extend in a direction oblique to the extension direction of the electrodes RME.

The light emitting elements ED disposed in each sub-pixel SPXn may emit light of different wavelength bands depending on a material constituting the semiconductor layer. However, the present disclosure is not limited thereto, and the light emitting elements ED arranged in each sub-pixel SPXn may include the semiconductor layer of the same material and emit light of the same color. The light emitting elements ED may be electrically connected to the electrode RME and the conductive layers below the via layer VIA while being in contact with the connection electrodes CNE (CNE1 and CNE2), and may emit light of a specific wavelength band by receiving an electrical signal.

The second insulating layer PAS2 may be disposed on the plurality of light emitting elements ED, the first insulating layer PAS1, and the bank layer BNL. The second insulating layer PAS2 extends in the first direction DR1 and includes a pattern portion disposed on the plurality of light emitting elements ED. The pattern portion is disposed to be partially around (or surround) the outer surface (e.g., outer peripheral surface) of the light emitting element ED, and may not cover both sides or both ends of the light emitting element ED. The pattern portion may form a linear or island-like pattern in each sub-pixel SPXn in a plan view. The pattern portion of the second insulating layer PAS2 may protect the light emitting element ED and fix the light emitting elements ED during a manufacturing process of the display device 10. Further, the second insulating layer PAS2 may be disposed to fill the space between the light emitting element ED and the first insulating layer PAS1 thereunder. Further, a part of the second insulating layer PAS2 may be disposed on the bank layer BNL and in the sub-regions SA. The part of the second insulating layer PAS2 disposed in the sub-region SA may not be disposed at the first contact portion CT1, the second contact portion CT2, and the separation portion ROP.

The plurality of connection electrodes CNE (CNE1 and CNE2) may be disposed on the plurality of electrodes RME and the light emitting elements ED, and may be in contact with each of them. The connection electrode CNE may be in contact with any one end of the light emitting element ED and at least one of the electrodes RME through the contact portions CT1 and CT2 penetrating the first insulating layer PAS1 and the second insulating layer PAS2.

The first connection electrode CNE1 may have a shape extending in the first direction DR1 and may be disposed on the first electrode RME1. The first connection electrode CNE1 may partially overlap the first electrode RME1 and may be disposed across the emission area EMA and the sub-region SA over the bank layer BNL. The first connection electrode CNE1 may be in contact with the first electrode RME1 through the first contact portion CT1 exposing the first electrode RME1 in the sub-region SA. The first connection electrode CNE1 may be in contact with the light emitting elements ED and the first electrode RME1 to transmit an electrical signal applied from the first transistor T1 and the first voltage wire VL1 to the light emitting element ED.

The second connection electrode CNE2 may have a shape extending in the first direction DR1 and may be disposed on the second electrode RME2. The second connection electrode CNE2 may partially overlap the second electrode RME2 and may be disposed across the emission area EMA and the sub-region SA over the bank layer BNL. The second connection electrode CNE2 may be in contact with the second electrode RME2 through the second contact portion CT2 exposing the second electrode RME2 in the sub-region SA. The second connection electrode CNE2 may be in contact with the light emitting elements ED and the second electrode RME2 to transmit an electrical signal applied from the second voltage wire VL2 to the light emitting element ED.

In one or more embodiments, the third insulating layer PAS3 is disposed on the second connection electrode CNE2 and the second insulating layer PAS2. The third insulating layer PAS3 may be disposed on the entire second insulating layer PAS2 to cover the second connection electrode CNE2, and the first connection electrode CNE1 may be disposed on the third insulating layer PAS3. The third insulating layer PAS3 may be disposed on the entire via layer VIA except the region where the first connection electrode CNE1 is disposed. The third insulating layer PAS3 may insulate the first connection electrode CNE1 and the second connection electrode CNE2 to prevent direct contact therebetween.

The third insulating layer PAS3 may be disposed in the entire sub-region SA except the portion where the first contact portion CT1 is disposed, and may cover the second contact portion CT2 and the separation portion ROP. Because the first connection electrode CNE1 is disposed at the first contact portion CT1, the third insulating layer PAS3 may expose the first contact portion CT1. Because the second connection electrode CNE2 is disposed at the second contact portion CT2, the third insulating layer PAS3 may cover the second contact portion CT2 together with the second connection electrode CNE2. Further, the third insulating layer PAS3 may cover the separation portion ROP and may be in direct contact with the top surface of the via layer VIA exposed by the electrodes RME spaced from each other.

In one or more embodiments, another insulating layer may be further disposed on the third insulating layer PAS3 and the first connection electrode CNE1. The insulating layer may function to protect the members disposed on the first substrate SUB against the external environment.

The first insulating layer PAS1, the second insulating layer PAS2, and the third insulating layer PAS3 described above may include an inorganic insulating material or an organic insulating material.

On the other hand, as described above, each of the electrodes RME of the display device 10 may include portions having different thicknesses or heights. The light emitting elements ED may be concentrated in a specific location in the manufacturing process depending on the thicknesses of the electrodes RME, so that it is possible to improve a degree of alignment and a loss rate of the light emitting elements ED arranged in each sub-pixel SPXn.

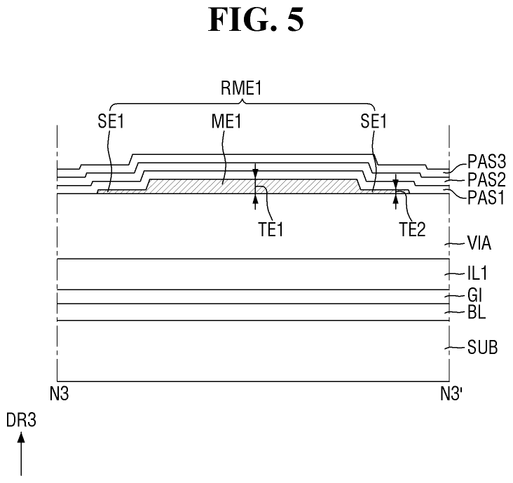

FIG. 5 is a cross-sectional view taken along the line N3-N3′ of FIG. 2. FIG. 5 shows a cross section of a portion of the first electrode RME1 of the first sub-pixel SPX1 disposed in the emission area EMA which is taken in the first direction DR1.

Referring to FIG. 5 in addition to FIGS. 2-4, in the display device 10, the electrodes RME may include main electrode portions ME1 and ME2 and sub-electrode portions SE1 and SE2 that are connected to both sides of the main electrode portions ME1 and ME2, respectively, in the first direction DR1. The first electrode RME1 may include the first main electrode portion ME1 and the plurality of first sub-electrode portions SE1, and the second electrode RME2 may include the second main electrode portion ME2 and the plurality of second sub-electrodes portions SE2. In one or more embodiments, the main electrode portions ME1 and ME2 and the sub-electrode portions SE1 and SE2 of the electrodes RME may be integrated and connected to each other, and the sub-electrode portions SE1 and SE2 may be located at opposite sides of the respective one of the main electrode portions ME1 and ME2 in the first direction DR1. In this case, the bottom surfaces of the main electrode portions ME1 and ME2 and the sub-electrode portions SE1 and SE2 may be directly disposed on the via layer VIA, and the main electrode portions ME1 and ME2 and the sub-electrode portions SE1 and SE2 may be distinguished depending on positions or structures thereof in one electrode RME. However, the present disclosure is not limited thereto, and in some cases, the main electrode portions ME1 and ME2 and the sub-electrode portions SE1 and SE2 may be formed as separate members and directly connected to each other to form one electrode RME.

Each of the main electrode portions ME1 and ME2 is disposed between the plurality of respective one of the sub-electrode portions SE1 and SE2 in the emission area EMA. Each of the sub-electrode portions SE1 and SE2 may be disposed across the emission area EMA and the sub-region SA to overlap the bank layer BNL. The first sub-electrode portion SE1, of the first electrode RME1, that is disposed on the upper side of the emission area EMA may be connected to the third conductive layer through the first electrode contact hole CTD at a portion overlapping the bank layer BNL in the third direction DR3, and the first sub-electrode portion SE1 of the first electrode RME1 that is disposed on the lower side of the emission area EMA may be in contact with the first connection electrode CNE1 through the first contact portion CT1 in the sub-region SA. Similarly, the second sub-electrode portion SE2, of the second electrode RME2, that is disposed on the upper side of the emission area EMA may be connected to the third conductive layer through the second electrode contact hole CTS at a portion overlapping the bank layer BNL in the third direction DR3, and the second sub-electrode portion SE2 of the second electrode RME2 that is disposed on the lower side of the emission area EMA may be in contact with the second connection electrode CNE2 through the second contact portion CT2 to be described later in the sub-region SA.

In accordance with one embodiment, the main electrode portions ME1 and ME2 of the electrodes RME may be thicker than the sub-electrode portions SE1 and SE2. A first thickness TE1 of the main electrode portions ME1 and ME2 may be greater than a second thickness TE2 of the sub-electrode portions SE1 and SE2, and the top surfaces of the main electrode portions ME1 and ME2 may be higher than those of the sub-electrode portions SE1 and SE2 with respect to the via layer VIA or the first substrate SUB. In one or more embodiments in which the main electrode portions ME1 and ME2 and the sub-electrode portions SE1 and SE2 are integrated as shown in FIG. 5, the difference in the heights of the top surfaces between the main electrode portions ME1 and ME2 and the sub-electrode portions SE1 and SE2 may be the same as the difference in the thicknesses TE1 and TE2 therebetween. Further, the heights of the top surfaces of the main electrode portions ME1 and ME2 and the sub-electrode portions SE1 and SE2 may be the same as the thicknesses TE1 and TE2, respectively, with respect to the top surface of the via layer VIA. In one embodiment, the first thickness TE1 of the main electrode portions ME1 and ME2 may be greater (e.g., two to four times greater) than the second thickness TE2 of the sub-electrode portions SE1 and SE2. Although the sub-electrode portions SE1 and SE2 may have the uniform second thickness TE2 as shown in FIG. 5, the present disclosure is not limited thereto and the sub-electrode portions SE1 and SE2 may have different thicknesses depending on positions.

The display device 10 may be manufactured by a process of injecting ink in which the light emitting elements ED are dispersed into the region surrounded by the bank layer BNL, and arranging the light emitting elements ED by applying an alignment signal to the electrodes RME. When different alignment signals are applied to different electrodes RME, an electric field is generated between the electrodes RME by the alignment signals, and the light emitting elements ED dispersed in the ink may be mounted on the electrodes RME with orientations and positions changed by the electric field.

The electric field may apply a force to the light emitting elements ED and the ink in which the light emitting elements ED are dispersed, and the light emitting elements ED may be located on the electrodes RME while moving with the ink flow. The direction and strength of the electric field generated between the first electrode RME1 and the second electrode RME2 may vary depending on positions in the region between the electrodes RME that are spaced from each other and the direction in which the electrodes RME extend. The direction or strength of the force applied to the light emitting elements ED and the ink may vary depending on the direction and strength of the electric field. For example, the alignment position of the light emitting element ED may be affected by the ink flow. Even when the light emitting elements ED are located on accurate positions, if the ink flow occurs, the alignment positions of the light emitting elements ED may be changed. That is, it is possible to align the light emitting elements ED at desired positions by guiding the ink flow toward a specific position or by guiding the ink flow in a specific direction.

The strength of the electric field generated between the electrodes RME may vary depending on the thicknesses of the electrodes RME, and the strength and direction of the force applied to the ink may vary depending on the strength of the electric field that may change the ink flow. The display device 10 may adjust the thicknesses of the electrodes RME to adjust the strength of the electric field, and may finally adjust the ink flow to align the light emitting elements ED to a specific position.

In one or more embodiments, the electrodes RME of the display device 10 may include the main electrode portions ME1 and ME2 and the sub-electrode portions SE1 and SE2 having different thicknesses, so that it is possible to guide the light emitting elements ED and the ink flow toward a specific direction in the step of aligning the light emitting elements ED. A relatively strong electric field may be generated between the thick main electrode portions ME1 and ME2, and the ink may flow outward from the main electrode portions ME1 and ME2, i.e., in the first direction DR1 or the second direction DR2 by the electric field. The flow of the ink moving, from the main electrode portions ME1 and ME2 to the sub-electrode portions SE1 and SE2, in the first direction DR1 may face the electric field generated between the sub-electrode portions SE1 and SE2. Because the thicknesses of the sub-electrode portions SE1 and SE2 are relatively smaller than those of the main electrode portions ME1 and ME2, the strength of the electric field generated on the sub-electrode portions SE1 and SE2 may be weak, and a reverse flow of the ink, i.e., a flow directed toward the main electrode portions ME1 and ME2, may be generated at the region where the main electrode portions ME1 and ME2 and the sub-electrode portions SE1 and SE2 are connected to each other. Further, the heights of the top surfaces of the main electrode portions ME1 and ME2 and the sub-electrode portions SE1 and SE2 may vary depending on the thicknesses thereof, and the reverse flow of the ink may be generated on the sub-electrode portions SE1 and SE2 due to the stepped portions between the main electrode portions ME1 and ME2 and the sub-electrode portions SE1 and SE2. Accordingly, the ink flow may stay on the main electrode portions ME1 and ME2 due to the reverse flow on the sub-electrode portions SE1 and SE2. The force of the ink flow that is guided to stay on the main electrode portions ME1 and ME2 in addition to the strong electric field generated between the main electrode portions ME1 and ME2 may be applied to the light emitting elements ED dispersed in the ink, and most of the light emitting elements ED may be arranged such that both ends thereof are located on the main electrode portions ME1 and ME2.

In one or more embodiments, in the display device 10, the amount of the light emitting elements ED arranged on the main electrode portions ME1 and ME2 of the electrodes RME may be higher than that of the amount of light emitting elements ED arranged on the sub-electrode portions SE1 and SE2. For example, the main electrode portions ME1 and ME2 may be arranged within the emission area EMA without being arranged on the upper side and the lower side of the emission area EMA, and the sub-electrode portions SE1 and SE2 may be arranged on the upper side and the lower side of the emission area EMA. Because the light emitting elements ED are guided to be arranged on the main electrode portions ME1 and ME2, the number of light emitting elements ED arranged at the central portion of the emission area EMA may be greater than the number of light emitting elements ED arranged on the upper side and the lower side of the emission area EMA.

Most of the light emitting elements ED may be arranged such that the opposite ends are located on different main electrode portions ME1 and ME2, and the light emitting elements ED arranged on the main electrode portions ME1 and ME2 may emit light effectively while being connected to the connection electrodes CNE. On the other hand, most of the light emitting elements ED arranged on the sub-electrode portions SE1 and SE2 or arranged in the other regions may not emit light without being connected to the connection electrodes CNE. The electrodes RME of the display device 10 may have a structure in which the light emitting elements ED are arranged on the main electrode portions ME1 and ME2. The display device 10 may reduce the loss rate of the light emitting elements ED and improve a degree of alignment of the light emitting elements ED, and may also improve a defective rate per each sub-pixel SPXn and luminous efficiency.

The main electrode portions ME1 and ME2 of the electrodes RME may be arranged in the emission area EMA so that most of the light emitting elements ED are arranged in a specific position in the emission area EMA. In one embodiment, the extension lengths of the main electrode portions ME1 and ME2 in the first direction DR1 may be shorter than the length of the emission area EMA, specified in the first direction DR1, which is opened by the bank layer BNL. The sub-electrode portions SE1 and SE2 may be partially arranged in the emission area EMA, and may extend from the corresponding one of the main electrode portions ME1 and ME2 in the first direction DR1 to be arranged across the bank layer BNL and the sub-region SA. Most of the light emitting elements ED may be positioned on the main electrode portions ME1 and ME2 arranged in the emission area EMA, so that it is possible to reduce the rate of the light emitting elements ED that are lost during the manufacturing process. However, the relationship between the shapes and the thicknesses of the electrodes RME is not limited to that shown in FIG. 5. The electrodes RME may have other shapes, if necessary, and the description thereof will be given with reference to another embodiment.

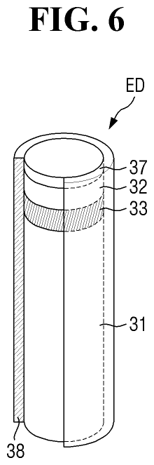

FIG. 6 is a schematic cutaway view of a light emitting element according to one embodiment.

Referring to FIG. 6, the light emitting element ED may be a light emitting diode. For example, the light emitting element ED may be an inorganic light emitting diode that has a nanometer or micrometer size, and is made of an inorganic material. The light emitting element ED may be aligned between two electrodes having polarity when an electric field is formed in a specific direction between two electrodes facing each other.

The light emitting element ED according to one embodiment may have a shape elongated in one direction. The light emitting element ED may have a shape of a cylinder, a rod, a wire, a tube, or the like. However, the shape of the light emitting element ED is not limited thereto, and the light emitting element ED may have a polygonal prism shape such as a regular cube, a rectangular parallelepiped and a hexagonal prism, or may have various shapes such as a shape elongated in one direction and having an outer surface partially inclined.

The light emitting element ED may include a semiconductor layer doped with any conductivity type (e.g., p-type or n-type) impurities. The semiconductor layer may emit light of a specific wavelength band by receiving an electrical signal applied from an external power source. The light emitting element ED may include a first semiconductor layer 31, a second semiconductor layer 32, a light emitting layer 33, an electrode layer 37, and an insulating layer 38.

The first semiconductor layer 31 may be an n-type semiconductor. The first semiconductor layer 31 may include a semiconductor material having a chemical formula of AlxGayIn1-x-yN (0≤x≤0, 0≤y≤1, 0≤x+y≤1). For example, the first semiconductor layer 31 may be any one or more of n-type doped AlGaInN, GaN, AlGaN, InGaN, AlN and InN. The n-type dopant doped into the first semiconductor layer 31 may be Si, Ge, Sn, or the like.

The second semiconductor layer 32 is disposed on the first semiconductor layer 31 with the light emitting layer 33 therebetween. The second semiconductor layer 32 may be a p-type semiconductor, and the second semiconductor layer 32 may include a semiconductor material having a chemical formula of AlxGayIn1-x-yN (0≤x≤1, 0≤y≤1, 0≤x+y≤1). For example, the second semiconductor layer 32 may be any one or more of p-type doped AlGaInN, GaN, AlGaN, InGaN, AlN and InN. The p-type dopant doped into the second semiconductor layer 32 may be Mg, Zn, Ca, Se, Ba, or the like.

Although it is illustrated in the drawing that each of the first semiconductor layer 31 and the second semiconductor layer 32 is configured as one layer, the present disclosure is not limited thereto. Depending on the material of the light emitting layer 33, the first semiconductor layer 31 and the second semiconductor layer 32 may further include a larger number of layers, such as a cladding layer or a tensile strain barrier reducing (TSBR) layer.

The light emitting layer 33 is disposed between the first semiconductor layer 31 and the second semiconductor layer 32. The light emitting layer 33 may include a material having a single or multiple quantum well structure. When the light emitting layer 33 includes a material having a multiple quantum well structure, a plurality of quantum layers and well layers may be stacked alternately. The light emitting layer 33 may emit light by coupling of electron-hole pairs according to an electrical signal applied through the first semiconductor layer 31 and the second semiconductor layer 32. The light emitting layer 33 may include a material such as AlGaN or AlGaInN. For example, when the light emitting layer 33 has a structure in which quantum layers and well layers are alternately stacked in a multiple quantum well structure, the quantum layer may include a material such as AlGaN or AlGaInN, and the well layer may include a material such as GaN or AlInN.

The light emitting layer 33 may have a structure in which semiconductor materials having large band gap energy and semiconductor materials having small band gap energy are alternately stacked, and may include other Group III-V semiconductor materials according to the wavelength band of the emitted light. The light emitted by the light emitting layer 33 is not limited to light of a blue wavelength band, but the active layer 33 may also emit light of a red or green wavelength band in some cases.

The electrode layer 37 may be located on the second semiconductor layer 32. In one or more embodiments, an electrode layer may be located on the first semiconductor layer 31 and/or another electrode layer may be located on the second semiconductor layer 32. The electrode layer 37 may be an ohmic connection electrode. However, the present disclosure is not limited thereto, and it may be a Schottky connection electrode. The light emitting element ED may include at least one electrode layer 37. The light emitting element ED may include one or more electrode layers 37, but the present disclosure is not limited thereto, and the electrode layer 37 may be omitted.

In the display device 10, when the light emitting element ED is electrically connected to an electrode RME or a connection electrode CNE, the electrode layer 37 may reduce the resistance between the light emitting element ED and the electrode RME or the connection electrode CNE. The electrode layer 37 may include a conductive metal. For example, the electrode layer 37 may include at least one of aluminum (Al), titanium (Ti), indium (In), gold (Au), silver (Ag), ITO, IZO, or ITZO.

The insulating layer 38 may be around (e.g., surround) the outer surfaces (e.g., outer peripheral surfaces) of the plurality of semiconductor layers and electrode layers described above. For example, the insulating layer 38 may be around (e.g., surround) at least the outer surface (e.g., the outer peripheral surface) of the light emitting layer 33, and may expose both ends of the light emitting element ED in the longitudinal direction. Further, in cross-sectional view, the insulating layer 38 may have a top surface, which is rounded in a region adjacent to at least one end of the light emitting element ED.

The insulating layer 38 may include a material having insulating properties, such as silicon oxide (SiOx), silicon nitride (SiNx), silicon oxynitride (SiOxNy), aluminum nitride (AINx), and aluminum oxide (AlOx). It is illustrated in the drawing that the insulating layer 38 is formed as a single layer, but the present disclosure is not limited thereto. In one or more embodiments, the insulating layer 38 may be formed in a multilayer structure having a plurality of layers that are stacked therein.

The insulating layer 38 may function to protect the different layers of the light emitting elements ED. The insulating layer 38 may prevent an electrical short circuit that is likely to occur at the light emitting layer 33 when an electrode to which an electrical signal is transmitted is in direct contact with the light emitting element ED. In addition, the insulating layer 38 may prevent a decrease in luminous efficiency of the light emitting element ED.

Further, the insulating layer 38 may have an outer surface (e.g., an outer peripheral surface) that is surface-treated. When the ink is sprayed on the electrodes, the light emitting elements ED may be aligned in such a way that the light emitting elements ED are dispersed on the electrodes. Here, the surface of the insulating layer 38 may be treated in a hydrophobic or hydrophilic manner in order to keep the light emitting elements ED in a dispersed state without aggregation with other light emitting elements ED adjacent in the ink.

Hereinafter, various embodiments of the display device 10 will be described with reference to other drawings.

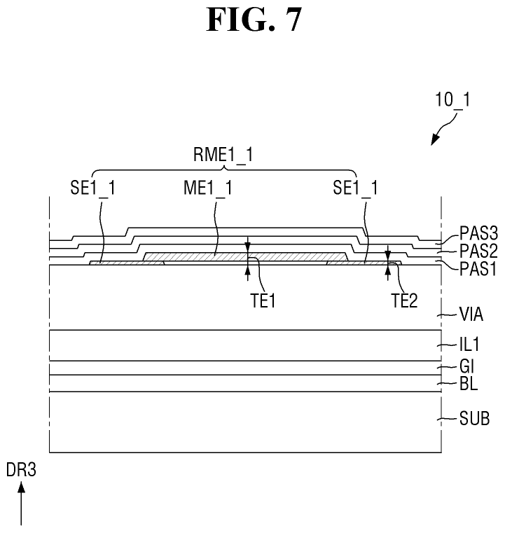

FIGS. 7-9 illustrate cross sections of one electrode of a display device according to one or more embodiments. FIGS. 7-9 show partial cross sections of the electrodes RME of display devices 10_1, 10_2, and 10_3 taken in the first direction DR, similarly to FIG. 5.

First, referring to FIG. 7, the display device 10_1 according to one or more embodiments may have a structure in which a first main electrode portion ME1_1 and first sub-electrode portions SE1_1 of a first electrode RME1_1 are formed as separate members and the first main electrode portion ME1_1 is disposed on the first sub-electrode portions SE1_1. The first sub-electrode portions SE1_1 may be spaced from each other in the first direction DR1, and the first main electrode portion ME1_1 may be disposed to overlap the first sub-electrode portions SE1_1 in the thickness direction of the substrate SUB (e.g., the third direction DR3) at both sides of the first direction DR1. The first main electrode portion ME1_1 and the first sub-electrode portions SE1_1 may be in direct contact with each other at the portions where they overlap. Even if the first main electrode portion ME1_1 and the first sub-electrode portions SE1_1 are formed as separate members, they may be in direct contact with each other and electrically connected.

Because the first main electrode portion ME1_1 is disposed on the first sub-electrode portions SE1_1, the bottom surface of the first main electrode portion ME1_1 may be separated from the top surface of the via layer VIA. Accordingly, the height of the top surface of the first main electrode portion ME1_1 measured from the top surface of the via layer VIA may be greater than the first thickness TE1 of the first main electrode portion ME1_1. Because the first main electrode portion ME1_1 is disposed on the first sub-electrode portions SE1_1, the first thickness TE1 may be smaller than the first thickness TE1 of the embodiment of FIG. 5 and may be greater than the second thickness TE2 of the first sub-electrode portion SE1_1. The embodiment of FIG. 7 is different from the embodiment of FIG. 5 in that a process of forming the first electrode RME1_1 may be divided into a process of forming the first sub-electrode portions SE1_1 and a process of forming the first main electrode portion ME1_1 on the first sub-electrode portions SE1_1. On the other hand, the second electrode RME2 may also have a structure in which the second main electrode portion ME2_1 is disposed on the second sub-electrode portions SE2_1.

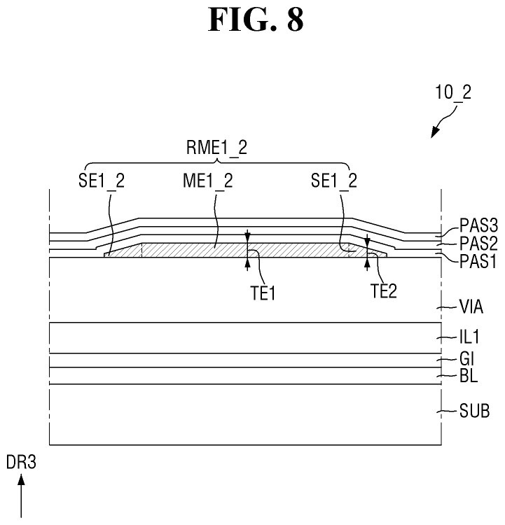

Next, referring to FIG. 8, the display device 10_2 according to one or more embodiments may have a shape in which a thickness TE2 of a first sub-electrode portion SE1_2 of a first electrode RME1_2 varies depending on positions. The embodiment of FIG. 8 is different from the embodiment of FIG. 5 in that the shape of the first sub-electrode portion SE1_2 is different. That is, a first main electrode portion ME1_2 and the first sub-electrode portions SE1_2 may be integrated and connected to each other, and the first sub-electrode portions SE1_2 may have a shape in which the thicknesses thereof become smaller in one direction from portions where the first sub-electrode portions SE1_2 are in contact with the first main electrode portion ME1_2. In one or more embodiments, the first sub-electrode portion SE1_2 may have the second thickness TE2 that is maximum at the portion where the first sub-electrode portion SE1_2 is in contact with the first main electrode portion ME1_2 and decreases as it becomes distant from the contact portion of the first main electrode portion ME1_2 and the first sub-electrode portion SE1_2 in the first direction DR1. The maximum thickness of the second thickness TE2 may be the same as the first thickness TE1 of the first main electrode portion ME1_2, and the minimum thickness of the second thickness TE2 may be the same as that of the embodiment of FIG. 5. On the other hand, the second electrode RME2 in one or more embodiments may have a structure in which the second main electrode portion ME2_2 is disposed on the second sub-electrode portions SE2_2.

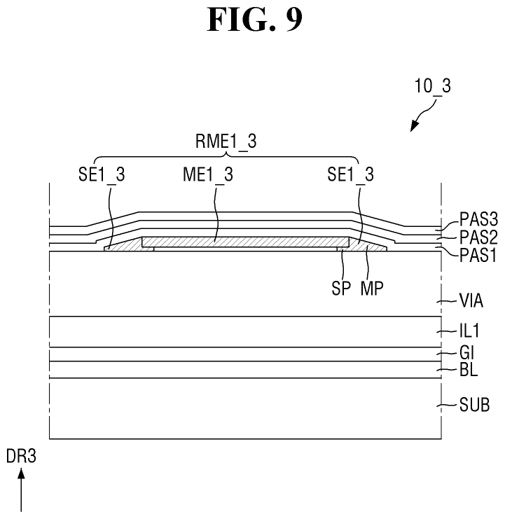

Next, referring to FIG. 9, the display device 10_3 according to one embodiment may have a shape in which a first main electrode portion ME1_3 and first sub-electrode portions SE1_3 of a first electrode RME1_3 are formed as separate members and the thicknesses of the first sub-electrode portions SE1_3 may partially vary. The first sub-electrode portion SE1_3 may have a first part SP on which one side of the first main electrode portion ME1_3 is disposed and a second part MP in contact with one side surface of the first main electrode portion ME1_3 and having a thickness that varies. Similarly to the embodiment of FIG. 7, the first electrode RME1_3 may have a structure in which the first main electrode portion ME1_3 is disposed on the first sub-electrode portions SE1_3 that are spaced from each other in the first direction DR1, and the first sub-electrode portion SE1_3 may have a shape in which its thickness partially varies. Alternatively, similarly to the embodiment of FIG. 8, the first electrode RME1_3 may have a structure in which the thicknesses of the first sub-electrode portions SE1_3 may vary depending on positions, and may have a stepped structure in which the first main electrode portion ME1_3 is disposed on the first sub-electrode portions SE1_3.

The first sub-electrode portion SE1_3 may have the first part SP that is stepped to have a smaller thickness from the surface where the second part MP is in contact with the side surface of the first main electrode portion ME1_3 in the first direction DR1. The bottom surfaces of both sides of the first main electrode portion ME1_3 may be in contact with the top surfaces of the first parts SP, and the side surfaces of the first main electrode portion ME1_3 may be in contact with the side surfaces of the second parts MP.

The second part MP of the first sub-electrode portion SE1_3 may have a shape in which its thickness becomes maximum at the portion that is in contact with the first main electrode portion ME1_3 and decreases as it becomes distant from that contact portion in the first direction DR1. The minimum thickness of the second part MP may be the same as the thickness of the first part SP. The first main electrode portion ME1_3 may be disposed on the first parts SP of the first sub-electrode portions SE1_3 and may be electrically connected to the first sub-electrode portions SE1_3 while being in direct contact with the first parts SP and the second parts MP. On the other hand, the second electrode RME2_3 may also have a structure in which the second main electrode portion ME2_3 is disposed on the second sub-electrode portions SE2_3.

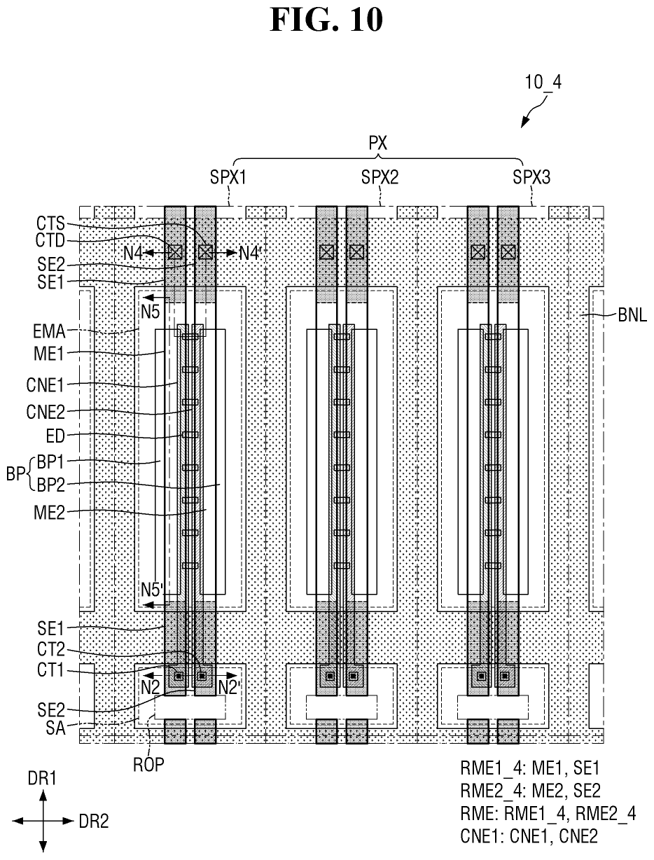

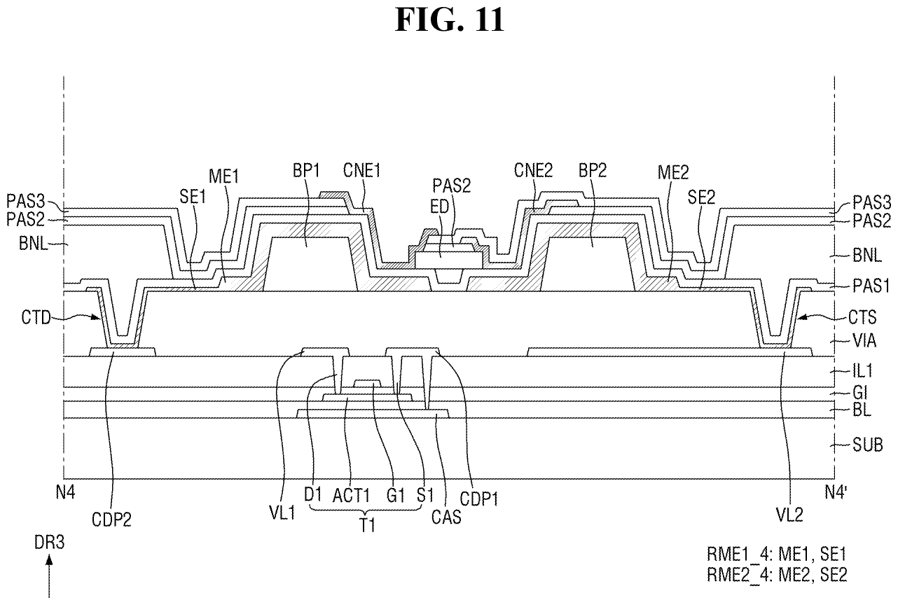

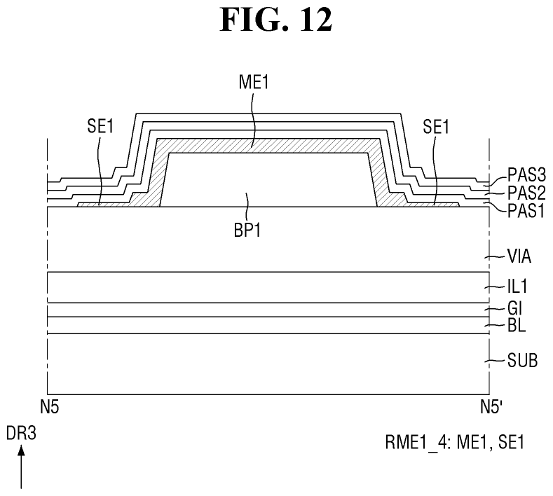

FIG. 10 is a plan view illustrating a pixel of a display device according to one or more embodiments. FIG. 11 is a cross-sectional view taken along the line N4-N4′ of FIG. 10. FIG. 12 is a cross-sectional view taken along the line N5-N5′ of FIG. 10. FIG. 11 shows a cross section across both ends of the light emitting element ED disposed in the first sub-pixel SPX1 of FIG. 10, and FIG. 12 shows a cross section of a part of the first electrode RME1 disposed in the first sub-pixel SPX1 that is taken in the first direction DR1.

Referring to FIGS. 10-12, a display device 10_4 according to one or more embodiments may further include bank patterns BP1 and BP2 that are arranged in each sub-pixel SPXn.

The plurality of bank patterns BP1 and BP2 may be directly disposed on the via layer VIA in the display area DPA. The bank patterns BP1 and BP2 may have a shape extending in the first direction DR1 and may be spaced from each other in the second direction DR2. For example, the bank patterns BP1 and BP2 may include a first bank pattern BP1 and a second bank pattern BP2 that are spaced from each other in the emission area EMA of each sub-pixel SPXn. The first bank pattern BP1 may be located on the left side that is one side in the second direction DR2 with respect to the central portion of the emission area EMA of the sub-pixel SPXn, and the second bank pattern BP2 may be located on the right side that is the other side in the second direction DR2 with respect to the central portion of the emission area EMA of the sub-pixel SPXn. The plurality of light emitting elements ED may be arranged between the first bank pattern BP1 and the second bank pattern BP2.

The extension lengths of the bank patterns BP1 and BP2 in the first direction DR1 may be smaller than the length of the emission area EMA that is surrounded by the bank layer BNL in the first direction DR1 and the second direction DR2. The bank patterns BP1 and BP2 may be arranged in the emission area EMA of the sub-pixel SPXn in the entire display area DPA to form an island-shaped pattern having a small width and extending in one direction. Although it is illustrated in the drawing that two bank patterns BP1 and BP2 having the same width are arranged for each sub-pixel SPXn, the present disclosure is not limited thereto. The number and the shape of the bank patterns BP1 and BP2 may vary depending on the number or the arrangement structure of the electrodes RME.

At least a part of each of the bank patterns BP1 and BP2 may protrude with respect to the top surface of the via layer VIA. The protruding parts of the bank patterns BP1 and BP2 may have inclined surfaces, and the light emitted from the light emitting element ED may be reflected by the electrode RME disposed on the bank patterns BP1 and BP2 and emitted in the upward direction of the via layer VIA. However, the present disclosure is not limited thereto, and the bank patterns BP1 and BP2 may have curved semicircular or semi-elliptical outer surfaces. The bank patterns BP1 and BP2 may include an organic insulating material such as polyimide (PI), but the present disclosure is not limited thereto.

In one or more embodiments, the top surfaces of the bank patterns BP1 and BP2 may be lower than the top surface of the bank layer BNL, and the thicknesses of the bank patterns BP1 and BP2 may be smaller than or equal to the thickness of the bank layer BNL. Unlike the bank layer BNL that prevents ink from overflowing to adjacent sub-pixels SPXn, the bank patterns BP1 and BP2 are arranged to partition the space where the light emitting elements ED are arranged or to form the inclined surfaces where the electrodes RME are arranged, so that the thicknesses or the heights of the bank patterns BP1 and BP2 may be different from that of the bank layer BNL.

A first electrode RME1_4 may be disposed on the first bank pattern BP1, and a second electrode RME2_4 may be disposed on the second bank pattern BP2. The first electrode RME1_4 and the second electrode RME2_4 may be arranged at least on the inclined surfaces of the bank patterns BP1 and BP2. In one or more embodiments, the widths of the plurality of electrodes RME measured in the second direction DR2 may be smaller than the widths of the bank patterns BP1 and BP2 measured in the second direction DR2. The first electrode RME1_4 and the second electrode RME2_4 may be arranged to cover at least one side surfaces of the bank patterns BP1 and BP2, respectively, and may reflect the light emitted from the light emitting element ED.

Further, the gap between the first electrode RME1_4 and the second electrode RME2_4 that are spaced from each other in the second direction DR2 may be smaller than the gap between the bank patterns BP1 and BP2 in the second direction DR2. The first electrode RME1_4 and the second electrode RME2_4 may be at least partially arranged directly on the via layer VIA, and may be located at the same plane.

In one embodiment, the portions of the electrodes RME arranged on the bank patterns BP1 and BP2 are the main electrode portions ME1 and ME2, and the sub-electrode portions SE1 and SE2 may be arranged without overlapping the bank patterns BP1 and BP2. The lengths of the main electrode portions ME1 and ME2 measured in the first direction DR1 may be greater than the lengths of the bank patterns BP1 and BP2 measured in the first direction DR1.

As described above, the light emitting elements ED may be concentrated on the main electrode portions ME1 and ME2 of the electrodes RME. Because only the main electrode portions ME1 and ME2 of the electrodes RME are arranged to overlap the bank patterns BP1 and BP2, the light emitting elements ED may be concentrated between the bank patterns BP1 and BP2. The bank patterns BP1 and BP2 may partially divide the emission area EMA into a plurality of regions due to the stepped portions, and the light emitting elements ED may be arranged between the bank patterns BP1 and BP2 where different electrodes RME are spaced from each other depending on the arrangement of the bank patterns BP1 and BP2 and the main electrode portions ME1 and ME2.

The pattern portion of the second insulating layer PAS2 may be disposed on the plurality of light emitting elements ED while extending in the first direction DR1 between the bank patterns BP1 and BP2. Further, the second insulating layer PAS2 and the third insulating layer PAS3 may be partially arranged on the bank patterns BP1 and BP2. The portions of the first connection electrode CNE1 and the second connection electrode CNE2 that are arranged on the main electrode portions ME1 and ME2 of the electrodes RME may overlap the bank patterns BP1 and BP2, respectively.

In one or more embodiments, the bank patterns BP1 and BP2 arranged on the via layer VIA are further included, and the light emitting elements ED may be arranged between the bank patterns BP1 and BP2. Further, because the bank patterns BP1 and BP2 have a shape protruding from the top surface of the via layer VIA and the electrodes RME are arranged to cover at least the side surfaces of the bank patterns BP1 and BP2, the light emitted from the light emitting element ED may be reflected by the electrodes RME disposed on the side surfaces of the bank patterns BP1 and BP2 and emitted in the upward direction of the first substrate SUB.

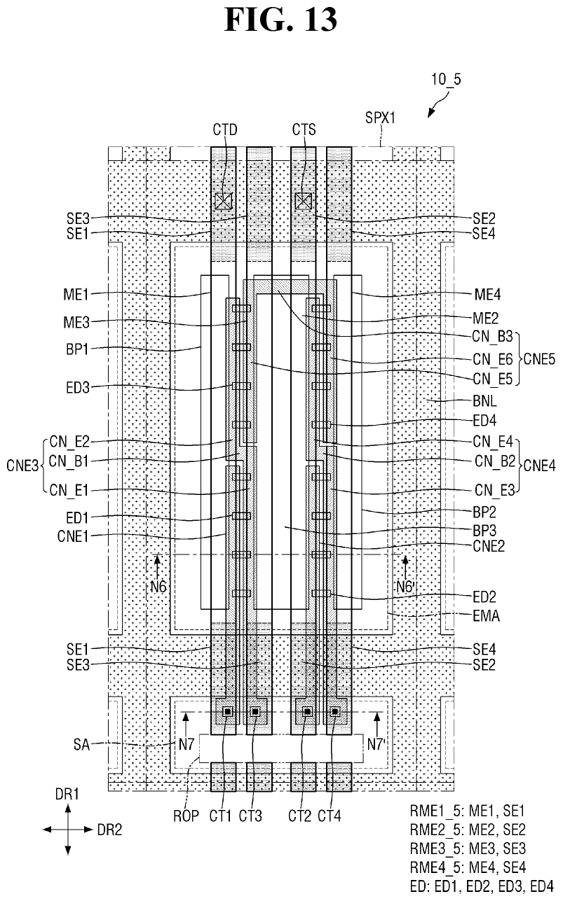

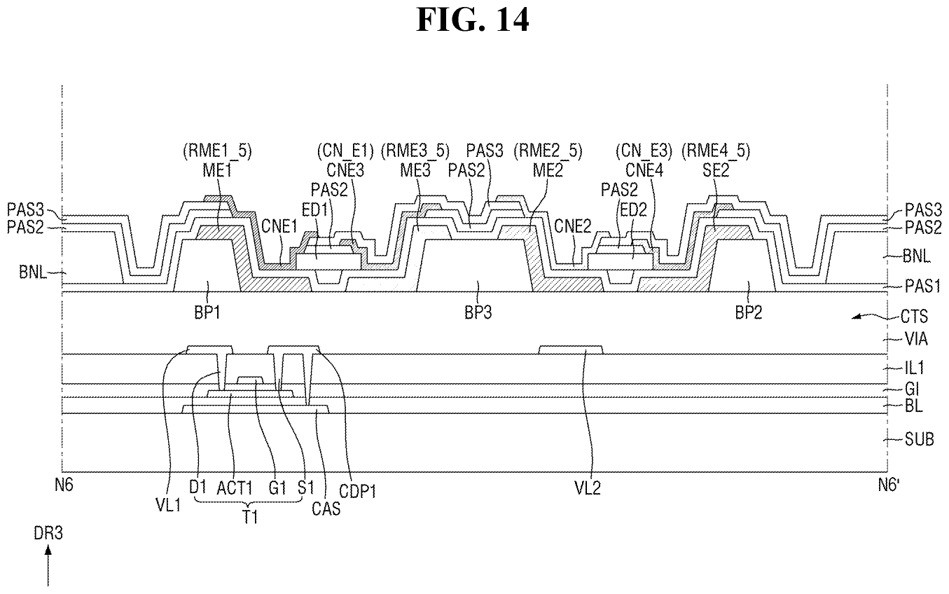

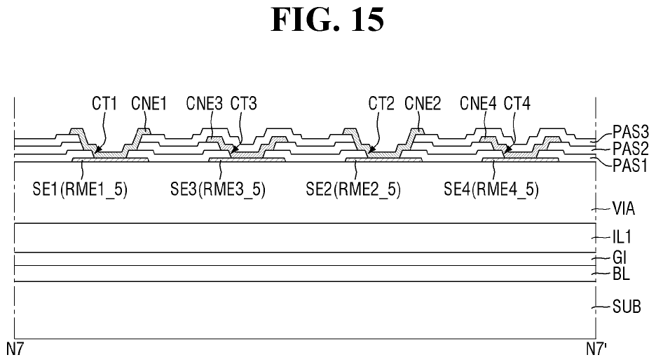

FIG. 13 is a plan view illustrating a sub-pixel of a display device according to one or more embodiments. FIG. 14 is a cross-sectional view taken along the line N6-N6′ of FIG. 13. FIG. 15 is a cross-sectional view taken along the line N7-N7′ of FIG. 13. FIG. 14 shows a cross section across both ends of the light emitting element ED disposed in the first sub-pixel SPX1 of FIG. 13, and FIG. 15 shows a cross section across contact portions CT1, CT2, CT3, and CT4 arranged in the sub-region SA of the first sub-pixel SPX1.

Referring to FIGS. 13-15, a display device 10_5 according to one or more embodiments may include a larger number of electrodes RME and a larger number of connection electrodes CNE, and the number of light emitting elements ED arranged in each sub-pixel SPXn may be increased. The embodiment of FIGS. 13-15 is different from the embodiment of FIGS. 10-12 in that the arrangement of the electrodes RME and the connection electrodes CNE of each sub-pixel SPXn is different and bank patterns BP1, BP2, and BP3 are provided. In the following description, a redundant description will be omitted and differences will be mainly described.

The bank patterns BP1, BP2, and BP3 may further include a third bank pattern BP3 disposed between the first bank pattern BP1 and the second bank pattern BP2. The first bank pattern BP1 may be located on the left side with respect to the center of the emission area EMA, the second bank pattern BP2 may be located on the right side with respect to the center of the emission area EMA, and the third bank pattern BP3 may be located at the center of the emission area EMA between the first bank pattern BP1 and the second bank pattern BP2. The width of the third bank pattern BP3 measured in the second direction DR2 may be greater than those of the first bank pattern BP1 and the second bank pattern BP2 measured in the second direction DR2. The gap between the bank patterns BP1, BP2, and BP3 in the second direction DR2 may be greater than the gap between the adjacent electrodes RME. Accordingly, at least parts of the electrodes RME may be arranged without overlapping the bank patterns BP1, BP2, and BP3.

The plurality of electrodes RME arranged for each sub-pixel SPXn may further include a third electrode RME3_5 and a fourth electrode RME4_5 in addition to a first electrode RME1_5 and a second electrode RME2_5.

The third electrode RME3_5 may be disposed between the first electrode RME1_5 and the second electrode RME2_5, and the fourth electrode RME4_5 may be spaced from the third electrode RME3_5 in the second direction DR2 with the second electrode RME2_5 interposed therebetween. The plurality of electrodes RME may be sequentially arranged in the order of the first electrode RME1_5, the third electrode RME3_5, the second electrode RME2_5, and the fourth electrode RME4_5 from the left side to the right side of the sub-pixel SPXn.

The electrodes RME may include main electrode portions ME1, ME2, ME3, and ME4 and a plurality of sub-electrode portions SE1, SE2, SE3, and SE4. As described above, the main electrode portions ME1, ME2, ME3, and ME4 of the electrodes RME may be arranged on the bank patterns BP1, BP2, and BP3 in the emission area EMA, and the sub-electrode portions SE1, SE2, SE3, and SE4 may be arranged across the emission area EMA and the sub-region SA over the bank layer BNL.

The first main electrode portion ME1 of the first electrode RME1_5 may be disposed on the first bank pattern BP1, and the first sub-electrode portions SE1 may be arranged respectively at both sides of the first main electrode portion ME1 in the first direction DR1. The second main electrode portion ME2 of the second electrode RME2_5 may be disposed on the third bank pattern BP3, and the second sub-electrode portions SE2 may be arranged respectively at both sides of the second main electrode portion ME2 in the first direction DR1.

The third main electrode portion ME3 of the third electrode RME3_5 may be disposed on the third bank pattern BP3 to face the first main electrode portion ME1. The third sub-electrode portions SE3 may be arranged respectively at both sides of the third main electrode portion ME3 in the first direction DR1. The fourth main electrode portion ME4 of the fourth electrode RME4_5 may be disposed on the second bank pattern BP2 to face the second main electrode portion ME2. The fourth sub-electrode portions SE4 may be arranged respectively at both sides of the fourth main electrode portion ME4 in the first direction DR1.

Among the plurality of electrodes RME, the first electrode RME1_5 and the second electrode RME2_5 may be connected to the third conductive layer disposed therebelow through the electrode contact holes CTD and CTS. However, the third electrode RME3_5 and the fourth electrode RME4_5 are not directly connected to the third conductive layer disposed therebelow, and may be electrically connected to the first electrode RME1_5 and the second electrode RME2_5 through the light emitting elements ED and the connection electrodes CNE. The first electrode RME1_5 and the second electrode RME2_5 may be first type electrodes in which the first sub-electrode portion SE1 and the second sub-electrode portion SE2 are directly connected to the third conductive layer through the electrode contact holes CTD and CTS, and the third electrode RME3_5 and the fourth electrode RME4_5 may be second type electrodes in which the third sub-electrode portions SE3 and the fourth sub-electrode portions SE4 are not directly connected to the third conductive layer. The second type electrodes may provide an electrical connection path of the light emitting elements ED together with the connection electrode CNE.

The plurality of light emitting elements ED may be arranged between the bank patterns BP1, BP2, and BP3 or on different electrodes RME. Some of the light emitting elements ED may be arranged between the first bank pattern BP1 and the third bank pattern BP3, and some other light emitting elements ED may be arranged between the third bank pattern BP3 and the second bank pattern BP2. In one or more embodiments, the light emitting element ED may include a first light emitting element ED1 and a third light emitting element ED3 arranged between the first bank pattern BP1 and the third bank pattern BP3, and a second light emitting element ED2 and a fourth light emitting element ED4 arranged between the third bank pattern BP3 and the second bank pattern BP2. The first light emitting element ED1 and the third light emitting element ED3 may be arranged respectively on the first main electrode portion ME1 of the first electrode RME1_5 and the third main electrode portion ME3 of the third electrode RME3_5. The second light emitting element ED2 and the fourth light emitting element ED4 may be arranged respectively on the second main electrode portion ME2 of the second electrode RME2_5 and the fourth main electrode portion ME4 of the fourth electrode RME4_5. The first light emitting element ED1 and the second light emitting element ED2 may be arranged adjacent to the lower side of the emission area EMA of the corresponding sub-pixel SPXn or adjacent to the sub-region SA, and the third light emitting element ED3 and the fourth light emitting element ED4 may be arranged adjacent to the upper side of the emission area EMA of the corresponding sub-pixel SPXn. However, the light emitting elements ED may not be classified depending on the arrangement positions in the emission area EMA, and may be classified depending on the connection relationship with the connection electrodes CNE to be described later. The light emitting elements ED may be in contact with different connection electrodes CNE at both ends thereof depending on the arrangement structure of the connection electrodes CNE, and may be classified into different light emitting elements ED depending on the types of the contact electrodes CNE to be in contact therewith.

The arrangement of the first insulating layer PAS1 may be the same as described with reference to the embodiment of FIGS. 2-4. The first insulating layer PAS1 may be disposed in the entire sub-pixel SPXn and may include the plurality of contact portions CT1, CT2, CT3, and CT4.

Because a larger number of electrodes RME are arranged for each sub-pixel SPXn, the number of the contact portions CT1, CT2, CT3, and CT4 may be increased. In one embodiment, in addition to the first contact portion CT1 disposed on the first sub-electrode portion SE1 of the first electrode RME1_5 and the second contact portion CT2 disposed on the second sub-electrode portion SE2 of the second electrode RME2_5, the third contract portion CT3 disposed on the third sub-electrode portion SE3 of the third electrode RME3_5, and the fourth contact portion CT4 disposed on the fourth sub-electrode portion SE4 of the fourth electrode RME4_5 may be further arranged in the sub-region SA. The contact portions CT1, CT2, CT3, and CT4 may penetrate the first insulating layer PAS1 and expose parts of the top surfaces of the sub-electrode portions SE1, SE2, SE3, and SE4 of the electrodes RME.

The plurality of connection electrodes CNE may further include, in addition to the first connection electrode CNE1 disposed on the first electrode RME1_5, the second connection electrode CNE2 disposed on the second electrode RME2_5, a third connection electrode CNE3, a fourth connection electrode CNE4, and a fifth connection electrode CNE5 arranged across the plurality of electrodes RME.

Unlike the embodiment of FIGS. 2-4, the extension length of each of the first connection electrode CNE1 and the second connection electrode CNE2 in the first direction DR1 may be relatively short. The first connection electrode CNE1 and the second connection electrode CNE2 may be arranged on the lower side with respect to the center of the emission area EMA. The first connection electrode CNE1 and the second connection electrode CNE2 may be arranged across the emission area EMA and the sub-region SA of the corresponding sub-pixel SPXn, and may be in contact with the first sub-electrode portion SE1 and the second sub-electrode portion SE2 through the first contact portion CT1 and the second contact portion CT2 formed in the sub-region SA, respectively.

The third connection electrode CNE3 may include a first extension portion CN_E1 disposed on the third electrode RME3_5, a second extension portion CN_E2 disposed on the first electrode RME1_5, and a first connection portion CN_B1 that connects the first extension portion CN_E1 to the second extension portion CN_E2. The first extension portion CN_E1 may be spaced from the first connection electrode CNE1 in the second direction DR2, and the second extension portion CN_E2 may be spaced from the first connection electrode CNE1 in the first direction DR1. The first extension portion CN_E1 may be disposed on the lower side of the emission area EMA of the corresponding sub-pixel SPXn, and the second extension portion CN_E2 may be disposed on the upper side of the emission area EMA. The first extension portion CN_E1 may be disposed across the emission area EMA and the sub-region SA, and may be connected to the third sub-electrode portion SE3 through the third contact portion CT3 formed in the sub-region SA. The first connection portion CN_B1 may be disposed across the first electrode RME1_5 and the third electrode RME3_5 at the central portion of the emission area EMA. The third connection electrode CNE3 may have a shape substantially extending in the first direction DR1, and may have a shape that is bent in the second direction DR2 and extends in the first direction DR1 again.

The fourth connection electrode CNE4 may include a third extension portion CN_E3 disposed on the fourth electrode RME4_5, a fourth extension portion CN_E4 disposed on the second electrode RME2_5, and a second connection portion CN_B2 that connects the third extension portion CN_E3 to the fourth extension portion CN_E4. The third extension portion CN_E3 may face and may be spaced from the second connection electrode CNE2 in the second direction DR2, and the fourth extension portion CN_E4 may be spaced from the second connection electrode CNE2 in the first direction DR1. The third extension portion CN_E3 may be disposed on the lower side of the emission area EMA of the corresponding sub-pixel SPXn, and the fourth extension portion CN_E4 may be disposed on the upper side of the emission area EMA. The third extension portion CN_E3 may be disposed in the emission area EMA and the sub-region SA and connected to the fourth sub-electrode portion SE4 through the fourth contact portion CT4. The second connection portion CN_B2 may be disposed across the second electrode RME2_5 and the fourth electrode RME4_5 while being adjacent to the center of the emission area EMA. The fourth connection electrode CNE4 may have a shape substantially extending in the first direction DR1, and may have a shape that is bent in the second direction DR2 and extends in the first direction DR1 again.

The fifth connection electrode CNE5 may include a fifth extension portion CN_E5 disposed on the third electrode RME3_5, a sixth extension portion CN_E6 disposed on the fourth electrode RME4_5, and a third connection portion CN_B3 that connects the fifth extension portion CN_E5 to the sixth extension portion CN_E6. The fifth extension portion CN_E5 may face and may be spaced from the second extension portion CN_E2 of the third connection electrode CNE3 in the second direction DR2, and the sixth extension portion CN_E6 may face and may be spaced from the fourth extension portion CN_E4 of the fourth connection electrode CNE4 in the second direction DR2. Each of the fifth extension portion CN_E5 and the sixth extension portion CN_E6 may be arranged on the upper side of the emission area EMA, and the third connection portion CN_B3 may be disposed across the third electrode RME3_5, the second electrode RME2_5, and the fourth electrode RME4_5. The fifth connection electrode CNE5 may be disposed to be around (or surround) the fourth extension portion CN_E4 of the fourth connection electrode CNE4 in a plan view.

The first connection electrode CNE1 and the second connection electrode CNE2 may be the first type connection electrodes in contact with the first electrode RME1_5 and the second electrode RME2_5 directly connected to the third conductive layer, respectively. The third connection electrode CNE3 and the fourth connection electrode CNE4 may be the second type connection electrodes in contact with the third electrode RME3_5 and the fourth electrode RME4_5, respectively, that are not directly connected to the third conductive layer. The fifth connection electrode CNE5 may be a third type connection electrode that is not in contact with the electrodes RME.

As described above, the plurality of light emitting elements ED may be classified into different light emitting elements ED depending on the connection electrodes CNE to be in contact with both ends of the light emitting elements ED to correspond to the arrangement structure of the connection electrodes CNE.

The first light emitting element ED1 and the second light emitting element ED2 may have first ends in contact with the first type connection electrodes and second ends in contact with the second type connection electrodes. The first light emitting element ED1 may be in contact with the first connection electrode CNE1 and the third connection electrode CNE3, and the second light emitting element ED2 may be in contact with the second connection electrode CNE2 and the fourth connection electrode CNE4. The third light emitting element ED3 and the fourth light emitting element ED4 may have first ends in contact with the second type connection electrodes and second ends in contact with the third type connection electrodes. The third light emitting element ED3 may be in contact with the third connection electrode CNE3 and the fifth connection electrode CNE5, and the fourth light emitting element ED4 may be in contact with the fourth connection electrode CNE4 and the fifth connection electrode CNE5.

The plurality of light emitting elements ED may be connected in series through the plurality of connection electrodes CNE. Because the display device 10_5 according to the embodiment of FIG. 13 includes a larger number of light emitting elements ED for each sub-pixel SPXn and the light emitting elements ED are connected in series, the light emission amount per unit area may be further increased.

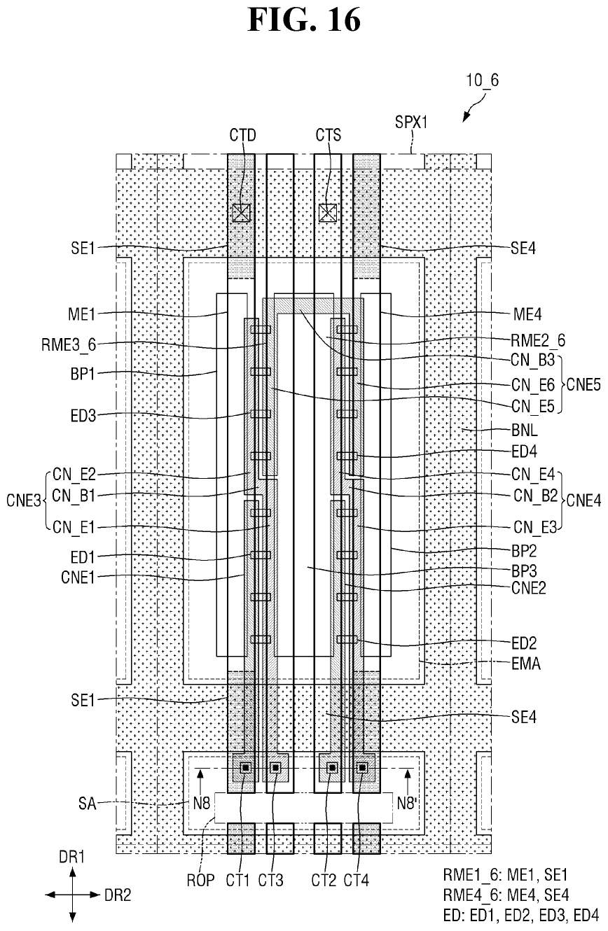

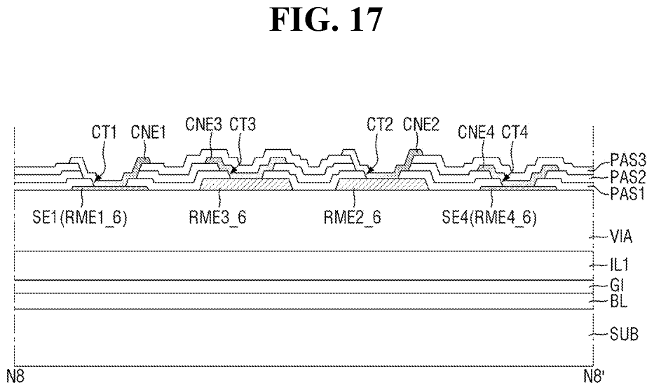

FIG. 16 is a plan view illustrating a sub-pixel of a display device according to one or more embodiments. FIG. 17 is a cross-sectional view taken along the line N8-N8′ of FIG. 16. FIG. 17 shows a cross section across the contact portions CT1, CT2, CT3, and CT4 arranged in the sub-region SA of the first sub-pixel SPX1 of FIG. 16.

Referring to FIGS. 16 and 17, in a display device 10_6 according to one or more embodiments, only some electrodes RME may include a main electrode portion and a sub-electrode portion, and other electrodes may not include a main electrode portion and a sub-electrode portion. For example, a first electrode RME1_6 and a fourth electrode RME4_6 include the main electrode portions ME1 and ME4 and the sub-electrode portions SE1 and SE4, respectively, but a second electrode RME2_6 and a third electrode RME3_6 may have a uniform thickness without being divided into different electrode portions. The embodiment of FIG. 16 is different from other embodiments in that only some electrodes RME include the main electrode portions ME1 and ME4 and the sub-electrode portions SE1 and SE4, and the other electrodes RME are formed as one member having the same thickness as those of the main electrode portions ME1 and ME4.

As described above, in the display device 10_6, the electrode RME may include the main electrode portions ME1 and ME4 and the sub-electrode portions SE1 and SE4, and the light emitting elements ED may be concentrated on the main electrode portions ME1 and ME4. In one or more embodiments in which each sub-pixel SPXn includes a larger number of electrodes RME, the structure of the electrodes RME may be partially changed if it is possible to control the ink flow such that the light emitting elements ED are located between the bank patterns BP1, BP2, and BP3. In one or more embodiments in which each sub-pixel SPXn includes four electrodes RME, if the first electrode RME1_6 and the fourth electrode RME4_6 arranged at the outermost part include the main electrode portions ME1 and ME4 and the sub-electrode portions SE1 and SE4, it is possible to control the ink flow toward the inner side thereof. Accordingly, the second electrode RME2_6 and the third electrode RME3_6 that are inner electrodes may not necessarily include the sub-electrode portions having a small thickness.

The portions of the electrodes RME that are disposed in the sub-region SA may have different thicknesses. The sub-electrode portions SE1 and SE4 of the first electrode RME1_6 and the fourth electrode RME4_6 may be arranged in the sub-region SA, and the sub-electrode portions SE1 and SE4 respectively exposed through the first contact portion CT1 and the fourth contact portion CT4 may have a relatively small thickness. On the other hand, the portions of the second electrode RME2_6 and the third electrode RME3_6 that are disposed in the sub-region SA and the portions of the second electrode RME2_6 and the third electrode RME3_6 that are disposed in the emission area EMA may have the same thickness, i.e., the thickness of the main electrode portions ME1 and ME4 of the other electrodes, and the portions exposed through the second contact portion CT2 and the third contact portion CT3 may have a relatively large thickness compared to those of the sub-electrode portions SE1 and SE2 of the other electrodes RME.

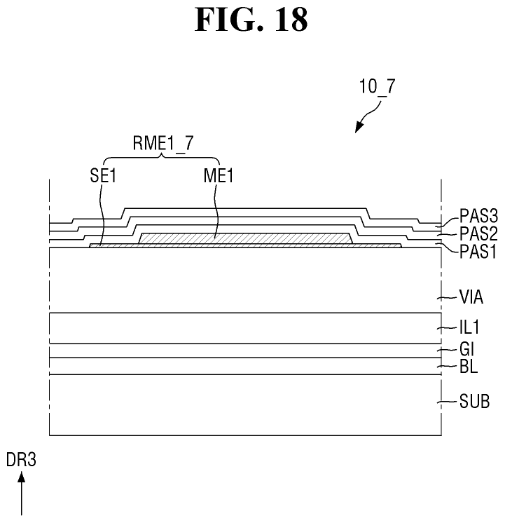

FIG. 18 is a diagram showing a cross section of one electrode of a display device according to one or more embodiments. FIG. 18 shows a partial cross section of a first electrode RME1_7 of a display device 10_7 that is taken in the first direction DR1, similarly to FIG. 5.

Referring to FIG. 18, the display device 10_7 according to one or more embodiments may have a shape in which one electrode RME, e.g., the first electrode RME1_7, includes one first sub-electrode portion SE1 and one first main electrode portion ME1, and the first main electrode portion ME1 is disposed on the first sub-electrode portion SE1. The first electrode RME1_7 may have a shape in which the first main electrode portion ME1 and the first sub-electrode portion SE1 are formed as separate members, the first sub-electrode portion SE1 extends in the first direction DR1, and the first main electrode portion ME1 is disposed on a part of the first sub-electrode portion SE1. The embodiment of FIG. 18 is different from the embodiment of FIG. 5 and the embodiment of FIG. 7 in that the first main electrode portion ME1 and the first sub-electrode portion SE1 are separated, and the first sub-electrode portion SE1 extends in the first direction DR1.

The structure of the first electrode RME1_7 may be partially changed if it is possible to guide the flow of the ink in which the light emitting elements ED are dispersed toward the upper part of the first main electrode portion ME1. Unlike the above-described embodiments, in the first electrode RME1_7, the first sub-electrode portion SE1 may be disposed across the emission area EMA and the sub-region SA while extending in the first direction DR1, and the first main electrode portion ME1 may be disposed on a part of the first sub-electrode portion SE1 disposed in the emission area EMA. That is, the extension length of the first main electrode portion ME1 in the first direction DR1 may be shorter than the extension length of the first sub-electrode portion SE1 in the first direction DR1. Even if the first sub-electrode portion SE1 is longer, because the first main electrode portion ME1 is not disposed on the upper side and the lower side of the emission area EMA, the light emitting elements ED may be concentrated on the first main electrode portion ME1 at the central portion of the emission area EMA.

In concluding the detailed description, those skilled in the art will appreciate that many variations and modifications can be made to the embodiments of the present disclosure without substantially departing from the spirit and scope of the present disclosure. Therefore, the embodiments of the present disclosure are used in a generic and descriptive sense only and not for purposes of limitation. The above and other aspects and features of embodiments of the present disclosure will become more apparent to one of ordinary skill in the art to which the present disclosure pertains by referencing the claims, with equivalents thereof to be included therein.

What is claimed is:

1. A display device comprising:
a first electrode and a second electrode extending in one direction on a substrate and spaced from each other;
a first insulating layer on the first electrode and the second electrode; and
a plurality of light emitting elements located on the first electrode and the second electrode, the plurality of light emitting elements being on the first insulating layer,
wherein each of the first electrode and the second electrode comprises a main electrode portion and a plurality of sub-electrode portions having a thickness smaller than that of the main electrode portion,
wherein the plurality of sub-electrode portions of each of the first electrode and the second electrode are connected to respective sides of the main electrode portion of the corresponding ones of the first electrode and the second electrode in the one direction, and
wherein at least one of both ends of a light emitting element of the plurality of light emitting elements is located on the main electrode portion of the first electrode or the second electrode.

2. The display device of claim 1, wherein both sides of the main electrode portion of each of the first electrode and the second electrode, in the one direction, are integrated and connected to the corresponding ones of the plurality of sub-electrode portions.

3. The display device of claim 2, wherein each of the plurality of sub-electrode portions has a thickness that decreases from one side that is in contact with the main electrode portion toward an other side.

4. The display device of claim 2, further comprising a via layer between the substrate and the first and second electrodes,
wherein each of the main electrode portions and the plurality of sub-electrode portions is directly on the via layer.

5. The display device of claim 1, wherein in each of the first electrode and the second electrode, the plurality of sub-electrode portions are spaced from each other in the one direction, and both sides of the main electrode portion of the first electrode or the second electrode in the one direction are on the corresponding ones of the plurality of sub-electrode portions.

6. The display device of claim 5, wherein each of the plurality of sub-electrode portions comprises a first part, wherein the main electrode portion is located on the first part of the sub-electrode portion, and a second part connected to the first part and in contact with the main electrode portion, and
wherein the second part has a thickness that decreases from one side that is in contact with the main electrode portion to an other side.

7. The display device of claim 5, further comprising a via layer between the substrate and the first and second electrodes,
wherein each of the plurality of sub-electrode portions is located directly on the via layer, and
wherein the main electrode portion has a bottom surface spaced from a top surface of the via layer.

8. The display device of claim 1, further comprising:
a first bank pattern located between the substrate and the first electrode; and
a second bank pattern located between the substrate and the second electrode,
wherein the main electrode portion of the first electrode is on the first bank pattern, and
wherein the main electrode portion of the second electrode is on the second bank pattern.

9. The display device of claim 8, wherein extension lengths of the first bank pattern and the second bank pattern in the one direction are less than extension lengths of the main electrode portions of the first electrode and the second electrode in the one direction.

10. The display device of claim 1, further comprising:
a bank layer around an emission area including the plurality of light emitting elements; and
a sub-region on one side of the emission area in the one direction,
wherein in each of the first electrode and the second electrode, the main electrode portion is located in the emission area, and the plurality of sub-electrode portions are located across the emission area and the sub-region over the bank layer.

11. The display device of claim 10, further including a plurality of electrode contact holes through a via layer at a portion where the first electrode and the second electrode and the bank layer overlap,
wherein in each of the first electrode and the second electrode, the plurality of sub-electrode portions are on the electrode contact holes.

12. The display device of claim 10, further comprising:
a first connection electrode on the first electrode and in contact with at least one of the plurality of light emitting elements; and
a second connection electrode on the second electrode and in contact with at least one of the plurality of light emitting elements,
wherein each of the first connection electrode and the second connection electrode is located across the emission area and the sub-region.

13. The display device of claim 12, wherein the first connection electrode is in contact with at least one of the plurality of sub-electrode portions of the first electrode in the sub-region, and
wherein the second connection electrode is in contact with at least one of the plurality of the sub-electrode portions of the second electrode in the sub-region.

14. A display device comprising:
a first electrode comprising a first main electrode portion extending in a first direction, and a plurality of first sub-electrode portions connected to both sides of the first main electrode portion in the first direction;
a second electrode spaced from the first electrode in a second direction and extending in the first direction;
a plurality of light emitting elements having one end located on the first electrode or the second electrode;
a first connection electrode on the first electrode and in contact with some of the plurality of light emitting elements; and
a second connection electrode on the second electrode and in contact with other ones of the plurality of light emitting elements,
wherein the first main electrode portion has a thickness greater than that of the first sub-electrode portions, and
wherein the plurality of light emitting elements comprises first light emitting elements having one end located on the first main electrode portion.

15. The display device of claim 14, wherein the second electrode comprises a second main electrode portion extending in the first direction; and a plurality of second sub-electrode portions connected to both sides of the second main electrode portion in the first direction, and
wherein the first light emitting elements have an other end located on the second main electrode portion.

16. The display device of claim 15, further comprising a first insulating layer on the first electrode and the second electrode,
wherein the first connection electrode is on the first main electrode portion and at least one of the first sub-electrode portions is in contact with at least one of the first sub-electrode portions through a first contact portion penetrating the first insulating layer, and
wherein the second connection electrode is on the second main electrode portion and the second sub-electrode portions is in contact with the plurality of second sub-electrode portions through a second contact portion penetrating the first insulating layer.

17. The display device of claim 15, further comprising a bank layer that is around an emission area including the plurality of light emitting elements, and a sub-region located on one side of the emission area in the first direction,
wherein each of the first main electrode portion and the second main electrode portion is located in the emission area, and
each of the first sub-electrode portions and the second sub-electrode portions is located across the emission area and the sub-region.

18. The display device of claim 14, further comprising:
a third electrode located between the first electrode and the second electrode; and
a fourth electrode spaced from the third electrode in the second direction with the second electrode interposed therebetween,
wherein the first light emitting elements are on the first electrode and the third electrode, and
wherein the plurality of light emitting elements further comprises second light emitting elements located on the second electrode and the fourth electrode.

19. The display device of claim 18, wherein each of the second electrode, the third electrode, and the fourth electrode comprises a main electrode portion extending in the first direction, and a plurality of sub-electrode portions connected to respective sides of the corresponding ones of the main electrode portions in the first direction,
wherein the first light emitting elements have an other end on a third main electrode portion of the third electrode, and
wherein the second light emitting elements have both ends located on a second main electrode portion of the second electrode and a fourth main electrode portion of the fourth electrode.

20. The display device of claim 18, wherein the fourth electrode comprises a fourth main electrode portion extending in the first direction, and a plurality of fourth sub-electrode portions connected to both sides of the fourth main electrode portion in the first direction,
wherein each of the second electrode and the third electrode has same thickness as the first main electrode portion,
wherein the first light emitting elements have an other end located on the third electrode, and
wherein the second light emitting elements have both ends located on the second electrode and the fourth main electrode portion of the fourth electrode.
